(19) United States
(12) Patent Application Publication
(10) Pub. No.: US 2015/0294977 A1
(43) Pub. Date: Oct. 15, 2015

(54) NONVOLATILE MEMORY DEVICE

(71) Applicants: SANG-LOK KIM, SEOUL (KR); YOUNGJIN JEON, HWASEONG-SI (KR); DEVRAJ RAJAGOPAL, SUWON-SI (KR); DONG-SU JANG, SEONGNAM-SI (KR); YONGHO CHO, YONGIN-SI (KR)

(72) Inventors: SANG-LOK KIM, SEOUL (KR); YOUNGJIN JEON, HWASEONG-SI (KR); DEVRAJ RAJAGOPAL, SUWON-SI (KR); DONG-SU JANG, SEONGNAM-SI (KR); YONGHO CHO, YONGIN-SI (KR)

(21) Appl. No.: 14/565,012

(22) Filed: Dec. 9, 2014

(30) Foreign Application Priority Data
Apr. 14, 2014 (KR) 10-2014-0044329

(51) Int. Cl. H01L 27/115

(52) U.S. Cl. CPC H01L 27/115; H01L 27/11524; H01L 27/11526; H01L 27/11551; H01L 27/1157; H01L 27/11573; H01L 27/11578

(57) ABSTRACT

A nonvolatile memory device includes a memory cell array including a plurality of cell strings each having a plurality of memory cells stacked in a direction perpendicular to a substrate, and a peripheral circuit region including a plurality of transistors electrically connected to the memory cell array through a plurality of conductive lines. Each of the transistors includes a gate electrode crossing an active region of the substrate in a first direction and source and drain regions in the active region at the opposite sides of the gate electrode. In at least one of the transistors, the number of source contact plugs connected to the source region is different from the number of drain contact plugs connected to the drain region.

### PRIORITY STATEMENT

This U.S. non-provisional patent application claims priority under 35 U.S.C. §119 to Korean Patent Application No. 10-2014-0044329, filed on Apr. 14, 2014, the entire contents of which are hereby incorporated by reference.

### BACKGROUND OF THE INVENTION

The inventive concept relates to semiconductor memories. More particularly, the inventive concept relates to a nonvolatile memory device.

A semiconductor memory device is a memory device which is embodied using semiconducting material such as silicon Si, germanium Ge, gallium arsenide GaAs, indium phosphide InP, etc. A semiconductor memory device may be classified as a volatile semiconductor memory device or a nonvolatile semiconductor memory device.

A volatile memory device loses its stored data when its power supply is interrupted. Examples of volatile memory devices include a static RAM (SRAM), a dynamic RAM (DRAM), and a synchronous DRAM (SDRAM). A nonvolatile memory device retains its stored data even when its power supply is interrupted. Examples of nonvolatile memory devices include a read only memory (ROM), a programmable ROM (PROM), an erasable and programmable ROM (EPROM), an electrically erasable and programmable ROM (EEPROM), a flash memory, a phase change RAM (PRAM), a magnetic RAM (MRAM), a resistive RAM (RRAM), and a ferroelectric RAM (FRAM). A flash memory may be classified s a NOR type flash memory or a NAND type flash memory.

To improve the integration of a semiconductor memory device, a semiconductor memory device having a three-dimensional array structure is being studied.

### SUMMARY

A nonvolatile memory device according to the inventive concept provide may include a memory cell array including a plurality of cell strings each having a plurality of memory cells stacked in a direction perpendicular to a substrate, and a peripheral circuit region including a plurality of transistors electrically connected to the memory cell array through a plurality of conductive lines. Each of the transistors includes a gate electrode crossing an active region of the substrate in a first direction and source and drain regions in the active region at both sides of the gate electrode.

According to one aspect of the inventive concept, in at least one of the transistors, the number of source contact plugs connected to the source region may be different from the number of drain contact plugs connected to the drain region.

According to another aspect of the inventive concept, in at least one of the transistors, the spacing between the source contact plugs connected to the source region is different from the spacing between the drain contact plugs connected to the drain region.

A nonvolatile memory device according to the inventive concept may have a cell array region and a peripheral circuit region, and include an array of memory cell transistors located in the cell array region and comprising memory cells stacked in a vertical direction, a horizontal array of peripheral transistors in the peripheral circuit region with each of the peripheral transistors including a gate electrode and source and drain regions at opposite sides of the gate electrode, respectively, source and drain contact plugs extending vertically from the source and drain regions of the peripheral transistors, and an interconnection layer including conductive lines extending in the cell array and peripheral circuit regions, and in which device the source contact plugs extend vertically between the source regions and the interconnection layer, the drain contact plugs extend vertically between the drain regions and the interconnection layer, the source and drain contact plugs and the memory cell transistors are electrically connected to the conductive lines such that the interconnection layer electrically connects the peripheral transistors to the memory cell transistors, and a greater number of the contact plugs extend between the drain region of one of the peripheral transistors and the interconnection layer than between the source region of that peripheral transistors and the interconnection layer.

### BRIEF DESCRIPTION OF THE FIGURES

FIG. 1 is a block diagram illustrating a nonvolatile memory device in accordance with some embodiments of the inventive concept.

FIG. 2 is a block diagram illustrating an example of the nonvolatile memory device of FIG. 1.

FIG. 3 is a perspective view illustrating a memory cell array and a peripheral circuit region of FIG. 1.

FIG. 4 is a cross-sectional view illustrating a memory cell array and a peripheral circuit region having some features in accordance with the inventive concept.

FIG. 5 is a plan view illustrating a part of one memory block BLKa among memory blocks BLK1˜BLKz of FIG. 3.

FIG. 6 is a sectional view, in perspective, of the memory block BLKa taken along line I-I′ of FIG. 5.

FIG. 7 is a cross-sectional view of the memory block BLKa taken along the line I-I′ of FIG. 5.

FIG. 8 is an enlarged view illustrating one of cell transistors MT of FIG. 7.

FIG. 9 is an equivalent circuit diagram of the memory block BLKa.

FIG. 10 is a plan view of the peripheral circuit region of FIGS. 1 through 3.

FIG. 11 is a plan view illustrating an example of a transistor.

FIG. 12 is a cross-sectional view of the transistor of FIG. 11 taken along line II-II′.

FIG. 13 is a cross-sectional view of the transistor of FIG. 11 taken along the line III-III′.

FIG. 14 is a plan view illustrating a first embodiment of a transistor that may constitute each of the transistors of the peripheral circuit region shown FIG. 10 in accordance with the inventive concept.

FIG. 15 is a cross-sectional view of the first embodiment of the transistor taken along line IV-IV′ of FIG. 14.

FIG. 16 is a cross-sectional view of the first embodiment of the transistor taken along the line V-V′ of FIG. 14.

FIG. 17 is a plan view illustrating a second embodiment of a transistor that may constitute each of the transistors of the peripheral circuit region shown FIG. 10 in accordance with the inventive concept.

FIG. 18 is a cross-sectional view of the second embodiment of the transistor taken along line VI-VI′ of FIG. 17.

FIG. 19 is a cross-sectional view of the second embodiment of the transistor taken along line VII-VII′ of FIG. 17.

FIG. 20 is a cross-sectional view of the second embodiment of the transistor taken along line VIII-VIII′ of FIG. 17.

FIG. 21 is a plan view illustrating a third embodiment of a transistor that may constitute each of the transistors of the peripheral circuit region shown FIG. 10 in accordance with the inventive concept.

FIG. 22 is a plan view illustrating a fourth embodiment of a transistor that may constitute each of the transistors of the peripheral circuit region shown FIG. 10 in accordance with the inventive concept.

FIG. 23 is a block diagram illustrating a memory system in accordance with some embodiments of the inventive concept.

FIG. 24 is a block diagram illustrating a memory system in accordance with some other embodiments of the inventive concept.

FIG. 25 is a block diagram illustrating a memory card in accordance with some embodiments of the inventive concept.

FIG. 26 is a diagram illustrating a solid state drive in accordance with some embodiments of the inventive concept.

FIG. 27 is a diagram illustrating a computing device in accordance with some embodiments of the inventive concept.

### DETAILED DESCRIPTION OF THE PREFERRED EMBODIMENTS

The inventive concept will be described more fully hereinafter with reference to the accompanying drawings, in which embodiments of the inventive concept are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. However, positional relationships between elements are accurately depicted. In some cases like numbers may designate like elements throughout the drawings while in other cases different reference numbers will designate like elements but in either case, correspondence between like elements in the different figures will be clear from the description to those skilled in the art.

It will also be understood that when an element or layer is referred to as being “on” or “connected to” another element or layer, it can be directly on or directly connected to the other element or layer or intervening elements or layers may be present. In contrast, when an element or layer is referred to as being “directly on” or “directly connected to” another element or layer, there are no intervening elements or layers present.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. The term “extending” will generally refer to the longest or lengthwise dimension of an element even when not explicitly stated as the figures and context of the description will make clear. The term “disposed at a position” or the like will generally refer to the footprint or longitudinal center of the element being referenced.

A nonvolatile memory device will be used as an example of a storage device or an electronic device for explaining a feature or function of the inventive concept. In particular, the inventive concept is described as exemplified by a NAND flash memory but the inventive concept is applicable to other types of nonvolatile memory devices such as a PRAM, a MRAM, an ReRAM, a FRAM, or a NOR flash memory.

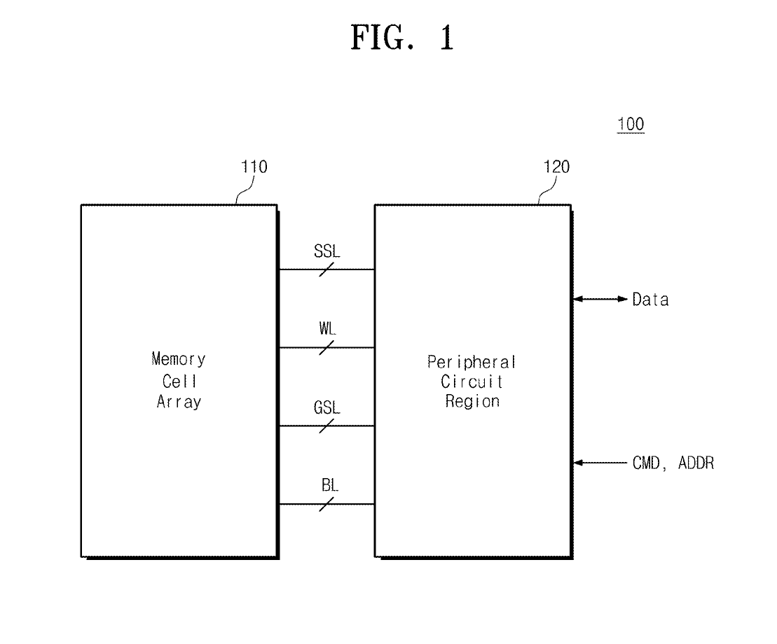

Referring to FIG. 1, the nonvolatile memory device 100 may include a memory cell array 110 and a peripheral circuit region 120.

The memory cell array 110 and the peripheral circuit region 120 can be connected to each other through string select lines SSL, ground select lines GSL and bit lines BL. The memory cell array 110 may include a plurality of memory blocks. Memory cells of each memory block can form a two-dimensional structure. Memory cells of each memory block can also be stacked in a direction perpendicular to a substrate to form a three-dimensional structure. Each memory block can include a plurality of memory cells and a plurality of select transistors. The memory cells can be connected to the word lines WL and the select transistors can be connected to the string select lines SSL or the ground select lines GSL. Memory cells of each memory block can store one or more bits.

The peripheral circuit region 120 can receive a command CMD and an address ADDR from the outside. The peripheral circuit region 120 can store data received from the outside in the memory cell array 110 according to the received command CMD and the address ADDR. The peripheral circuit region 120 can also output data read from the memory cell array 110 according to the received command CMD and the address ADDR.

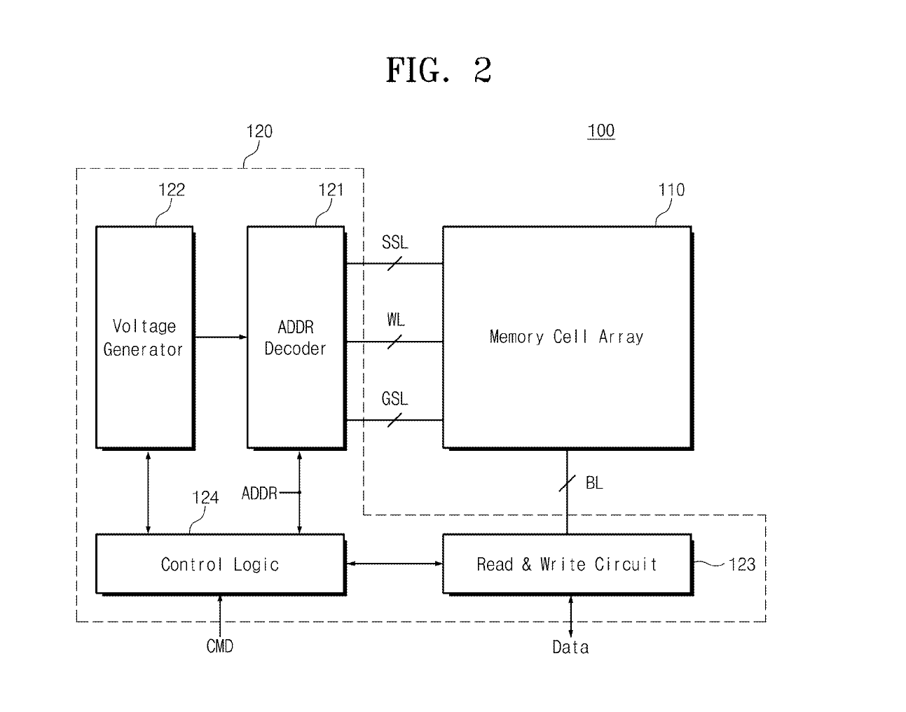

Referring to FIG. 2, peripheral circuit region 120 may include an address decoder 121, a voltage generator 122, a read & write circuit 123, and control logic 124.

The memory cell array 110 is connected to the address decoder 121 through string select lines SSL, ground select lines GSL and word lines WL and connected to the read & write circuit 123 through bit lines BL. The memory cell array 110 may include a plurality of memory blocks.

More specifically, in this example the address decoder 121 is connected to the memory cell array 110 through the string select lines SSL, the word lines WL, and the ground select lines GSL. The address decoder 121 is configured to operate in response to a control of the control logic 124. The address decoder 121 receives an address ADDR from the outside.

The address decoder 121 is configured to decode a row address among the received addresses ADDR. Using the decoded row address, the address decoder 121 selects string select lines SSL, word lines WL, and ground select lines GSL. The address decoder 121 can receive various voltages from the voltage generator 122 and transfer the received voltages to selected and unselected string lines SSL, word lines WL and ground select lines GSL, respectively.

The address decoder 121 may be configured to decode a column address among the transmitted addresses ADDR. The decoded column address (DCA) can be transmitted to the read & write circuit 130. The address decoder 121 may include constituent elements such as a row decoder, a column decoder and an address buffer.

The voltage generator 122 is configured to generate various voltages required by the nonvolatile memory device 100. For example, the voltage generator 122 can generate a plurality of program voltages, a plurality of pass voltages, a plurality of select read voltages and a plurality of unselect read voltages.

The read & write circuit 123 is connected to the memory cell array 110 through bit lines BL and can exchange data with the outside. The read & write circuit 123 operates in response to a control of the control logic 124. The read & write circuit 123 may be configured to receive a decoded column address DCA from the address decoder 121. Using the decoded column address DCA, the read & write circuit 123 can select bit lines BL.

The read & write circuit 123 can receive data from the outside and write the received data in the memory cell array 110. The read & write circuit 123 can read data from the memory cell array 110 and transmit the read data to the outside. The read & write circuit 123 can read data from a first storage area of the memory cell array 110 and write the read data in a second storage area of the memory cell array 110. For example, the read & write circuit 123 may be configured to perform a copy-back operation.

The read & write circuit 123 may include constituent elements such as a page buffer (or page register), a column select circuit, and a data buffer. The read & write circuit 123 may also include constituent elements such as a sense amplifier, a write driver, a column select circuit, and a data buffer.

The control logic 124 can be connected to the address decoder 121, the voltage generator 122 and the read & write circuit 123. The control logic 124 is configured to control an overall operation of the nonvolatile memory device 100. The control logic 124 operates in response to a command CMD being transmitted from a controller.

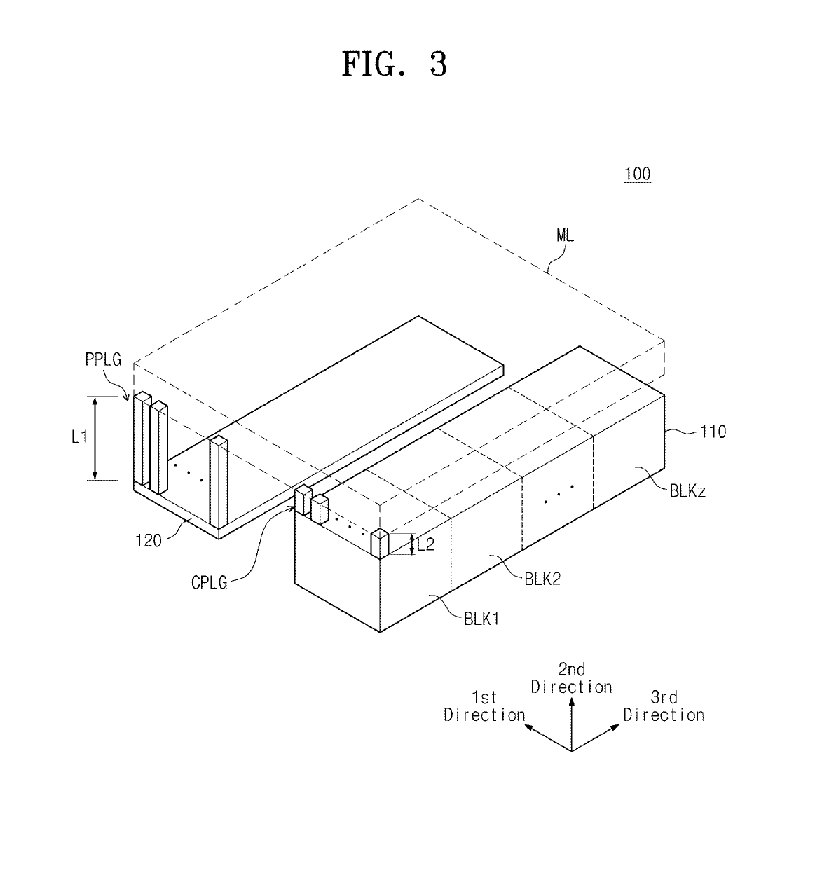

Referring to FIG. 3, the memory cell array 110 and the peripheral circuit region 120 are connected to each other through a metal (wiring) layer ML including at least one layer of metal wiring. The metal layer ML is formed on and spans the memory cell array 110 and the peripheral circuit region 120. The memory cell array 110 can be connected to the metal layer ML through cell plugs CPLG. The peripheral circuit region 120 can be connected to the metal layer ML through peripheral plugs PPLG.

The memory cell array 110 may have a three-dimensional structure (or a vertical structure). For example, memory blocks BLK1˜BLKz may form a structure extending upright in a second direction relative to a plane extending along first and third directions (in a Cartesian system of the first, second and third directions). The peripheral circuit region 120 has a planar structure. Mores specifically, the peripheral circuit region 120 lies essentially in a plane extending along the first and third directions. Thus, the length L2 of the cell plugs CPLG of the memory cell array 110 and the length L1 of the peripheral plugs PPLG of the peripheral circuit region 120 may be different from each other. In particular, the length L1 of the peripheral plugs PPLG may be greater than the length L2 of the cell plugs CPLG. For example, the length L1 may be twice the length L2.

As the length of the peripheral plugs PPLG becomes greater, a capacitance between the metal layer ML and a substrate in the peripheral circuit region 120 may increase. As the capacitance between the metal layer ML and the substrate increases, a propagation delay of the peripheral circuit region 120 may increase.

The peripheral circuit region 120 may include a plurality of transistors to perform various functions. Each transistor may include a gate electrode and source drain regions symmetrically disposed with respect to the gate electrode. The source region can be connected to the metal layer ML through the peripheral plugs PPLG. The drain region can also be connected to the metal layer ML through the peripheral plugs PPLG.

In one example of the nonvolatile memory device 100, the peripheral plugs PPLG associated with the source regions can be disposed asymmetrically to the peripheral plugs PPLG associated with the drain regions relative to the gate electrodes. For example, the number of the peripheral plugs PPLG connected to the drain regions may be less than the number of the peripheral plugs PPLG connected to the source regions. Thus, transistors of the peripheral circuit region 120 may have a reduced capacitance. Accordingly, propagation delay of the peripheral circuit region 120 may be reduced.

In FIG. 3, the cell plugs CPLG and the peripheral plugs PPLG are illustrated atop ends of the memory cell array 110 and the peripheral circuit region 120. However, the cell plugs CPLG may be provided atop any part of the memory cell array 110. The peripheral plugs PPLG may be provided atop any part of the peripheral circuit region 120.

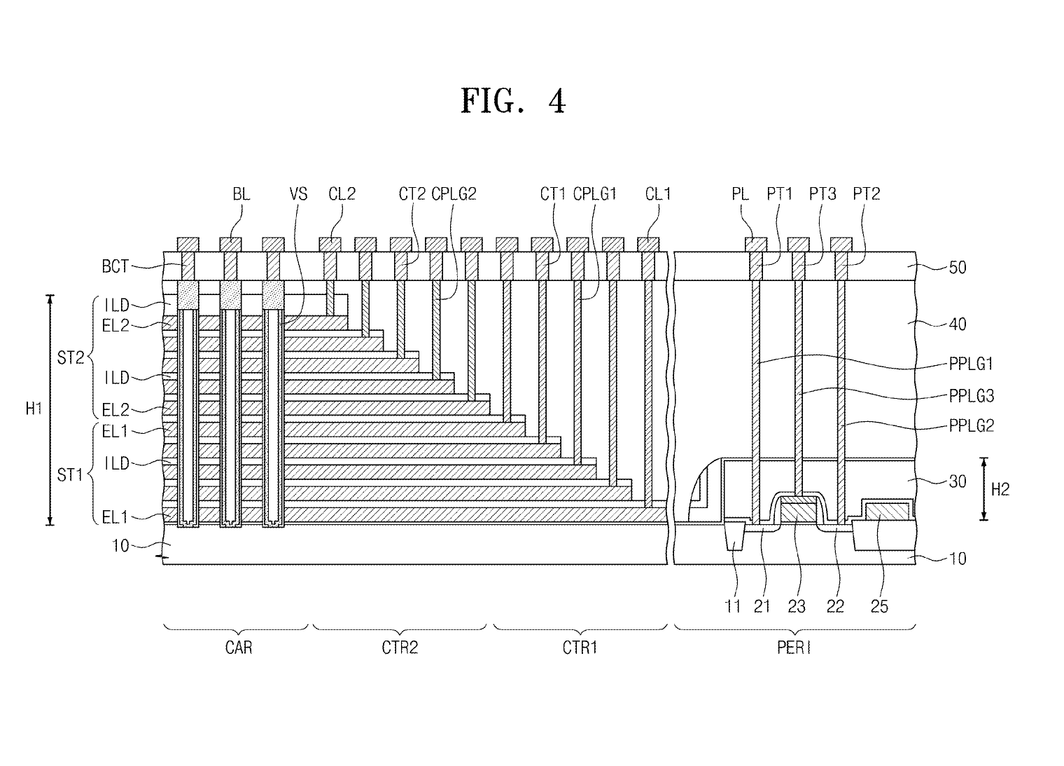

Referring to FIG. 4, the substrate 10 may span several regions of the device including a cell array region CAR, a peripheral circuit region PERI, and a contact region between the cell array region CAR and the peripheral circuit region PER1. The contact region may include a first contact region CTR1 adjacent to the peripheral circuit region PERI and a second contact region CTR2 adjacent to the cell array region CAR. The peripheral circuit region PERI may include an active region ACT of the substrate 10 defined by a device isolation layer 11.

The substrate 10 may be of material having a semiconductor characteristic (e.g., a silicon wafer) or an insulating characteristic (e.g., glass), or may be a multi-layered structure including a semiconductor or conductor covered with an insulating material. For example, the substrate 10 may be a silicon wafer having a first conductivity type.

A cell array structure is disposed in the cell array region CAR and a peripheral logic structure is disposed in the peripheral circuit region PERI. The cell array structure may have a first height H1 from a top surface of the substrate 10 and can extend from the cell array region CAR to the contact region. The peripheral logic structure may have a second height H2 smaller than the first height H1.

The cell array structure is a stacked structure including electrodes vertically stacked on the substrate 10 and vertical structures penetrating the stacked structure. In the cell array region CAR, the stacked structure may be have a linear footprint by extending essentially in one direction along the top surface of the substrate or may have a rectangular footprint by covering the entire surface of the substrate in the cell array region CAR. The stacked structure may have the form of steps on the contact regions to facilitate an electrical connection between the electrodes and the peripheral logic structure. That is, the height of the stacked structure on the contact regions may gradually increase in a direction towards the cell array region CAR from the peripheral circuit region PERI. That is, the stacked structure may have a sloped profile in the contact regions.

The stacked structure may include a first stacked structure ST1 including a plurality of first electrodes EL1 vertically stacked on the substrate 10 and a second stacked structure ST2 including second electrodes EL2 vertically stacked on the first stacked structure ST1.

The first stacked structure ST1 includes insulating layers ILD between vertically adjacent ones of the first electrodes EL1. The insulating layers ILD may have the same thickness or some of the insulating layers ILD may have different thicknesses. End parts of the first electrodes EL1 are disposed in the first contact region CTR1 and the first stacked structure ST1 may be stepped in the first contact region CTR1. The footprint (surface area) of the first electrodes EL1 may decrease in an upward direction away from the top surface of the substrate 10. Similarly, the second stacked structure ST2 includes insulating layers ILD between vertically adjacent one of the second electrodes EL2. The insulating layers ILD may have the same thickness or some of the insulating layers ILD may have different thicknesses. End parts of the second electrodes EL2 are disposed in the second contact region CTR2 and the second stacked structure ST2 may be stepped in the second contact region CTR2. The footprint (surface area) of the second electrodes EL2 may decrease in an upward direction away from the top surface of the substrate 10.

Vertical structures VS can penetrate the first and second stacked structures ST1 and ST2 to be connected to the substrate 10. The vertical structures VS may include semiconductor material or conductive material. The vertical structures VS may be aligned in a specific direction as viewed in plan. Alternatively, the vertical structures VS may be disposed in a zigzag along a particular direction as viewed in plan.

Bit lines BL crossing the stacked structure in a third direction may be disposed on a top surface of the cell array structure. The bit lines BL can be electrically connected to the vertical structures VS through bit line contacts.

A buried insulating layer 40 covering the stacked structure and the peripheral logic structure may be disposed over the entire top surface of the substrate 10. The buried insulating layer 40 has a planarized top surface and can cover end parts of the first and second stacked structures ST1 and ST2.

An interconnection structure for electrically connecting the cell array structure to the peripheral circuit structure may be disposed on the first and second stacked structures ST1 and ST2. According to an embodiment of the inventive concept, first plugs PLG1 penetrating the buried insulating layer 40 to be connected to end parts of the first electrodes EL1 may be disposed in the first contact region CTR1. Second plugs PLG2 penetrating the buried insulating layer 40 to be connected to end parts of the second electrodes EL2 may be disposed in the second contact region CTR2. The vertical lengths (i.e., the heights) of the first cell plugs CPLG1 decrease in a direction towards the cell array region CAR from the peripheral circuit region PERI. The vertical lengths (i.e., the heights) of the second cell plugs CPLG2 also decrease in a direction towards the cell array region CAR from the peripheral circuit region PERI. The smallest of the vertical lengths of the first cell plugs CPLG1 may be greater than the largest of the vertical lengths of the second cell plugs CPLG2. Top surfaces of the first and second cell plugs CPLG1 and CPLG2 may be coplanar. Furthermore, the top surfaces of the first and second cell plugs CPLG1 and CPLG2 may be coplanar with top surfaces of the vertical structures VS.

First cell interconnection lines CL1 electrically connected to the first cell plugs CPLG1 through first cell contacts CT1 may be disposed on the buried insulating layer 40 of the first contact region CTR1. Second cell interconnection lines CL2 electrically connected to the second cell plugs CPLG2 through second cell contacts CT2 may be disposed on the buried insulating layer 40 of the second contact region CTR2.

As described with reference to FIG. 2, the peripheral logic structure of the peripheral circuit region PERI may include the address decoder 121, the voltage generator 122, the read & write circuit 123 and the control logic 124. That is, the peripheral logic structure may include NMOS and PMOS transistors, a resistor and a capacitor that are electrically connected to the cell array structure.

A device isolation layer 11 defining an active region ACT may be formed in the substrate 10 of the peripheral circuit region PERI. The peripheral logic structure of the peripheral circuit region PERI may include a gate electrode 23 crossing the active region ACT in the third direction, source and drain regions 21 and 22 formed in the active region ACT at both sides of the gate electrode 23 and a peripheral insulating pattern 30 covering the peripheral circuits. The peripheral logic structure may include a resistance pattern 25 (serving as a resistor of the peripheral logic circuit) and the peripheral insulating pattern 30 can cover the gate electrode 23 and the resistance pattern 25. A tope surface of the peripheral insulating pattern 30 may be located below a top surface of the cell array structure.

Peripheral interconnection lines PL may be disposed on the buried insulating layer 40 of the peripheral circuit region PERI. The peripheral interconnection lines PL can extend from the peripheral circuit region PERI to the cell array region CAR. The peripheral interconnection lines PL may be formed of the same conductive material as the bit lines of the cell array region CAR.

The peripheral interconnection lines PL can extend in parallel along the third direction perpendicular to a first direction. Parts of the peripheral interconnection lines PL may overlap the active region ACT as viewed in plan. That is, the peripheral interconnection lines PL may be disposed on the active region ACT.

From a vertical viewpoint, a first peripheral plug PPLG1 may be disposed between the source region 21 and the peripheral interconnection lines PL. A second peripheral plug PPLG2 may be disposed between the drain region 22 and the peripheral interconnection lines PL. A third peripheral plug PPLG3 may be disposed between the gate electrode 23 and the peripheral interconnection lines PL.

The first through third peripheral plugs PPLG1, PPLG2 and PPLG3 may be horizontally spaced apart from one another along the first direction. The first through third peripheral plugs PPLG1, PPLG2 and PPLG3 may be disposed on the active region ACT.

Vertical lengths of the first and second peripheral plugs PPLG1 and PPLG2 may be greater than the greatest of the vertical lengths of the first cell plugs CPLG1. A vertical length of the third peripheral plug PPLG3 may be greater than the greatest of the vertical lengths of the second cell plugs CPLG2 and may be smaller than the greatest of the vertical lengths of the first cell plugs CPLG1. Top surfaces of the first through third peripheral plugs PPLG1, PPLG2 and PPLG3 may be substantially coplanar with top surfaces of the first and second cell plugs CPLG1 and CPLG2 of the first and second contact regions CTR1 and CTR2. Top surfaces of the first through third peripheral plugs PPLG1, PPLG2 and PPLG3 may be substantially coplanar with top surfaces of the vertical structure VS of the cell array region CAR.

The first through third peripheral plugs PPLG1, PPLG2 and PPLG3 are illustrated in the peripheral circuit region PERI but the inventive concept is not limited thereto. For example, at least one of the first through third peripheral plugs PPLG1, PPLG2 and PPLG3 may be omitted or a greater number of peripheral plugs may be provided.

The first peripheral plug PPLG1 can be electrically connected to the source region 21. The second peripheral plug PPLG2 can be electrically connected to the drain region 22. The third peripheral plug PPLG3 can be electrically connected to the gate electrode 23.

Furthermore, each of the first through third peripheral plugs PPLG1, PPLG2 and PPLG3 can be electrically connected to the peripheral interconnection lines PL through peripheral contacts PT1, PT2 and PT3. According to an embodiment of the inventive concept, the first through third peripheral contacts PT1, PT2 and PT3 may be aligned with the first through third peripheral plugs PPLG1, PPLG2 and PPLG3, respectively, but locations of the first through third peripheral contacts PT1, PT2 and PT3 depend on the electrical connection between the peripheral interconnection lines PL and the peripheral logic circuits. Top surfaces of the first through third peripheral contacts PT1, PT2 and PT3 can be substantially coplanar with top surfaces of the first and second cell contacts CT1 and CT2 of the first and second contact regions CTR1 and CTR2.

Furthermore, the bit line contacts BCT, the first and second cell contacts CT1 and CT2 and the first through third peripheral contacts PT1, PT2 and PT3 may be omitted. Thus, the bit lines BL can be directly connected to the vertical structures VS. The first and second cell interconnection lines CL1 and CL2 can be directly connected to the first and second cell plugs CPLG1 and CPLG2. The peripheral interconnection lines PL can be directly connected to the first through third peripheral plugs PPLG1, PPLG2 and PPLG3.

As viewed in plan, although the first through third peripheral contacts PT1, PT2 and PT3 are located at a boundary between the active region ACT and the device isolating layer 11 or on the device isolation layer 11, they can be electrically connected to the peripheral logic structure through the first through third peripheral plugs PPLG1, PPLG2 and PPLG3.

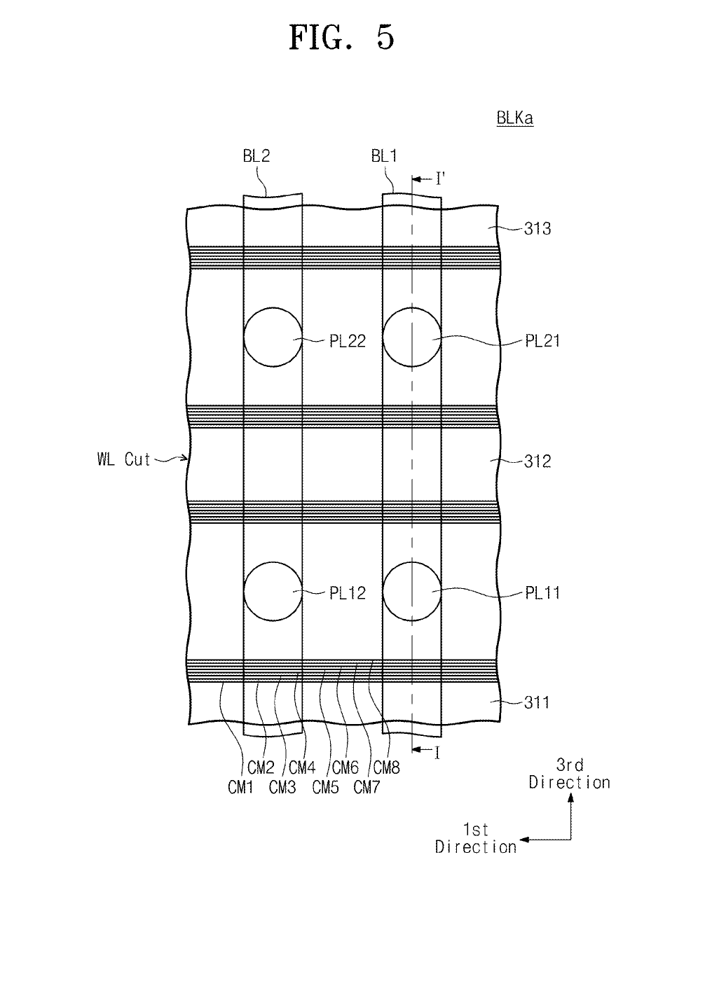

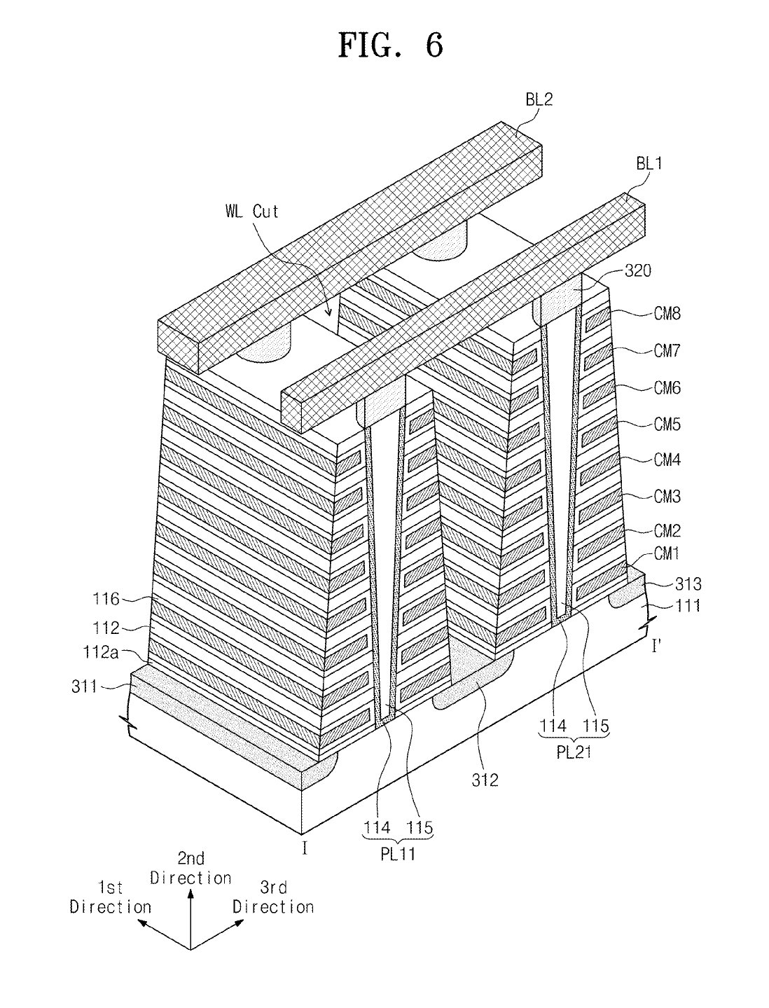

FIGS. 5 through 7 illustrate an example of a memory block BLKa that may be employed as any of the memory blocks BLK1, BLK2 . . . BLKz in the device 100 shown in and described above with respect to FIG. 2.

A substrate 111 is provided. The substrate 111 may comprise a well having a first conductivity type. For example, the substrate 111 may comprise a bulk substrate and a P well 111 formed by injecting a group-III element into an upper portion of the bulk substrate. The P well may be provided inside an N well. For purposes of description, the present embodiment will be described as including a substrate having a P well (or a pocket P well). However, the conductivity type of the region (e.g., well) of the substrate is not limited to a P conductivity type.

Doping regions extending in the first direction are provided in the substrate 111. The doping regions are spaced a specific distance apart from each other along the third direction. The doping regions may include a first doping region 311, a second doping region 312 and a third doping region 313.

The first through third doping regions 311˜313 have a second conductivity type different from the substrate 111. In this example, therefore, the first through third doping regions 311˜313 have an N conductivity type.

Insulators 112 and 112a (which in the alternative may be referred to hereinafter as insulating layers 112 and 112a) are stacked on the substrate 111, i.e., in the second direction perpendicular to the substrate. The insulators 112 and 112a are spaced from one another along the second direction. The insulators 112 and 112a extend in the first direction between adjacent ones of the doping regions 311˜313. The insulators 112 and 112a each comprise a layer of electrically insulating material such as a silicon oxide layer. The insulator 112a which is in contact with the substrate 111 may be thinner than the other insulators 112.

Pillars PL11, PL12, PL21 and PL22 are provided between adjacent ones of the first through third doping regions 311˜313. The pillars PL11, PL12, PS21 and PL22 extend through the insulators 112 and 112a in the second direction, and can contact the substrate 111. Each of the pillars PL11, PL12, PS21 and PL22 is a multi-layered structure. For example, each of the pillars PL11, PL12, PS21 and PL22 may include a channel layer 114 and internal material 115 surrounded by the channel layer 114.

The channel layer 114 may include a semiconductor material (e.g., silicon) having the first conductivity type, i.e., the same conductivity type as the substrate 111. For example, the channel layer 114 may include silicon. In an example of this embodiment, the channel layers 114 are layers of silicon doped to have a P type of conductivity. Alternatively, the channel layer 114 may comprise a layer of intrinsic semiconductor material not having a particular conductivity type.

The internal material 115 includes electrically insulating material. For example, the internal material 115 may include silicon oxide. Alternatively, the internal material 115 may be omitted so that an empty space (air) is left within the channel layer 114. In either case, therefore, the medium within the channel layer 114 is electrically insulating.

Information storage layers 116 are also provided between adjacent ones of the first through third doping regions 311˜313. The information storage layers 116 extend along and contact surfaces of the insulating layers 112 and 112a and the pillars PL11, PL12, PS21 and PL22. The thickness of the information storage layers 116 may be smaller than the distance between adjacent ones of the insulating layers 112 and 112a in the second direction.

Conductors CM1˜CM8 (which in the alternative may be referred to hereinafter as conductive layers CM1˜CM8) are also provided between ones of the first through third doping regions 311-313. The conductors CM1˜CM8 are of electrically conductive material and may each comprise a metallic layer. Alternatively, the conductors CM1˜CM8 may each include a nonmetallic electrically conductive material such as doped polysilicon.

The conductors CM1˜CM8 extend along and contact surfaces of the information storage layers 116. Specifically, for example, each of the conductors CM1˜CM8 extends in the first direction between and contacts a segment of an information storage layer 116 disposed on the bottom surface of an upper one of the insulating layers and a segment of the information storage layer 116 provided on a top surface of a lower one of the insulating layers.

Drains 320 may be provided on the pillars PL11, PL12, PL21 and PL22, respectively. In particular, the drains 320 may extend on upper parts of the channel layers 114 of the pillars PL11, PL12, PL21 and PL22. The drains 320 may include a semiconductor material (e.g., silicon) doped so as to have a particular conductivity type. In the example of this embodiment, the drains 320 are of silicon doped so as to have an N conductivity type.

Bit lines BL1 and BL2 that extend in the third direction, and are spaced apart from one another in the first direction, are provided on the drains 320. The bit lines BL1 and BL2 are electrically connected to the drains 320. The drains 320 can be connected to the bit lines BL1 and BL2 through bit line contacts (not shown in this figure). The bit lines BL1 and BL2 are of electrically conductive material, i.e., are of metallic material or nonmetallic conductive material such as doped polysilicon.

The pillars PL11, PL12, PS21 and PL22 can be arrayed in the first and second directions such that rows and columns of the pillars PL11, PL12, PL21 and PL22 of the memory block BLKa are defined.

In this respect, the conductive layers CM1˜CM8 and the insulating layers 112 and 112a may be divided by a word line cut WL cut. The word line cut WL may be aligned with the second doping region 312 as the center, and divides the pillars into rows.

In the illustrated example, the pillars PL11 and PL12 connected by the conductive layers CM1˜CM8 and the information storage layers 116, which are disposed between the first doping region 311 and the second doping region 312, constitute a first row of the pillars. The pillars PL21 and PL22 connected by the conductive layers CM1˜CM8 and the information storage layers 116, which are disposed between the second doping region 312 and the third doping region 313, constitute a second row of the pillars.

Columns of the pillars PL11, PL12, PL21 and PL22 are defined according to the bit lines BL1 and BL2. In the illustrated example, the pillars PL11 and PL21 connected to each other through the first bit line BL1 and respective drains 320 constitute a first column of the pillars. The pillars PL12 and PL22 connected to each other through the second bit line BL2 and the drain 320 constitute a second column of the pillars.

Each of the pillars PL11, PL12, PL21 and PL22 forms a cell string together with adjacent information storage layers 116 and adjacent conductive layers CM1˜CM8. Thus, the pillars PL11, PL12, PL21 and PL22 form a plurality of cell strings together with information storage layers 116 and conductive layers CM1˜CM8. Each cell string includes a plurality of cell transistors MT stacked in a direction perpendicular to the substrate 111.

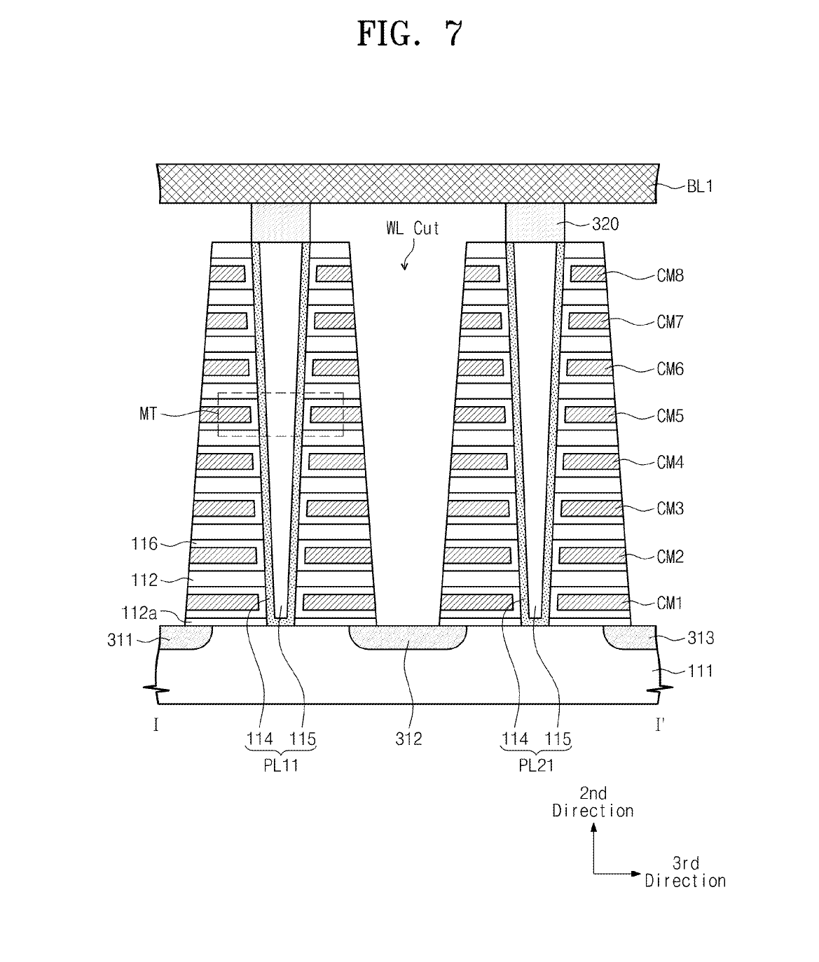

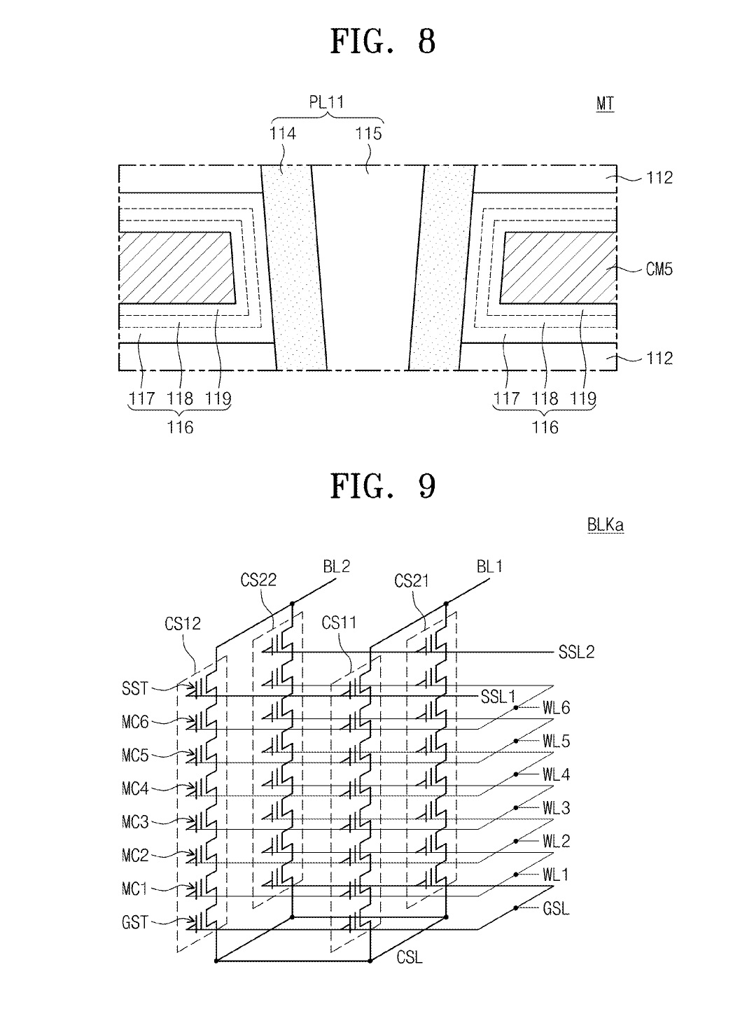

FIG. 8 illustrates an exemplary one of the cell transistors MT and in particular, the cell transistor MT shown in FIG. 7 within the dashed line. This cell transistor is disposed at the fifth level, among the levels of cell transistors MT, and comprises the pillar PL11 that makes up both the first row and first column of the pillars.

Referring to FIGS. 5 through 8, the cell transistor MT includes the fifth conductive layer CM5, a part of the pillar PL11 adjacent to the fifth conductive layer CM5 and the information storage layer 116 interposed between the fifth conductive layer CM5 and the pillar PL11. The information storage layer 116 in this example includes first through third insulating sub-layers 117, 118 and 119.

In the cell transistors MT, and as mentioned above, the channel layers 114 of the pillars PL11, PL12, PL21 and PL22 may include p-type silicon similarly to the substrate 111. The channel layers 114 operate as a body of the cell transistor MT. The channel layers 114 are vertical channel layers in that extend in a direction perpendicular to the substrate 111. Thus, each of the channel layers 114 of the pillars PL11, PL12, PL21 and PL22 acts a vertical body of the memory transistors MT of a cell string. Channels formed in each of the channel layers 114 of the pillars PL11, PL12, PL21 and PL22 form vertical channels of the memory transistors MT of the cell string.

The first insulating sub-layers 117 adjacent to the pillars PL11, PL12, PL21 and PL22 operate as tunneling insulating layers. To this end, the first insulating sub-layers 117 may comprise thermal oxide layers. For example, each first insulating sub-layer 117 may include a silicon oxide layer.

Second insulating sub-layers 118 operate as charge storage layers. For example, the second insulating sub-layers 118 can operate as charge capturing layers. For example, the second insulating sub-layers 118 may each comprise a nitride layer or a metallic oxide layer (e.g., an aluminum oxide layer, a hafnium oxide layer, or the like). In this example, each of the second insulating sub-layers 118 is a silicon nitride layer.

Third insulating sub-layers 119 adjacent to the conductive layers CM1˜CM8 operate as blocking insulating layers. The third insulating sub-layers 119 may each consist of a single layer or a laminate (multiple layers). The third insulating sub-layers 119 may each be a dielectric layer (e.g., an aluminum oxide layer, a hafnium oxide layer, or the like) having a dielectric constant higher than each of those of the first and second insulating sub-layers 117 and 118. The first through third insulating sub-layers 117˜119 may constitute an ONO (oxide-nitride-oxide) structure.

The conductive layers CM1˜CM8 operate as gates (or control gates).

Therefore, in this example, the conductive layers CM1˜CM8 operating as gates (or control gates), the third insulating sub-layers 119 operating as blocking insulating layers, the second insulating sub-layers 118 operating as charge capturing layers, the first insulating sub-layers 117 operating as tunneling insulating layers and the channel layers 114 operating as a vertical body constitute the cell transistors MT.

Respective ones of the cell transistors MT may be charge capturing transistors. However, others of the cell transistors MT may be used for different purposes. For example, among the cell transistors MT, at least one cell transistor at an upper portion of each cell string may be used as a string select transistor SST, at least one cell transistor at a lower portion of the cell string may be used as a ground select transistor GST, and the remaining cell transistors may be memory cell transistors and may include at least one dummy memory cell transistor. In this respect, the conductive layers CM1˜CM8 also serve as conductive lines connecting the cell transistors MT of the same row to one another. Therefore, each conductive layer CM1˜CM8 may constitute a string select line SSL, a ground select line GSL, a word line WL, or a dummy word line DWL, depending on their level in the cell string.

FIG. 9 shows an example of an equivalent circuit of the memory blocks BLK.

In this example shown in FIGS. 5 through 9, cell strings CS11 and CS21 are provided between the first bit line BL1 and a common source line CSL. Cell strings CS12 and CS22 are provided between the second bit line BL2 and the common source line CSL. The cell strings CS11, CS21, CS12 and CS22 comprise the pillars PL11, PL21, P12 and P22, respectively.

More specifically, in this example, the pillar PL11 of a first row and a first column constitutes the string CS11 of a first row and a first column together with the conductive layers CM1˜CM8 and the information storage layers 116. The pillar PL12 of a first row and a second column constitutes the string CS12 of a first row and a second column together with the conductive layers CM1˜CM8 and the information storage layers 116. The pillar PL21 of a second row and a first column constitutes the string CS21 of a second row and a first column together with the conductive layers CM1˜CM8 and the information storage layers 116. The pillar PL22 of a second row and a second column constitutes the string CS22 of a second row and a second column together with the conductive layers CM1˜CM8 and the information storage layers 116.

In the cell strings CS11, CS21, CS12 and CS22, the first (lower) level of cell transistors operate as ground select transistors GST. Cell strings of the same row share a ground select line GSL. Cell strings of different rows also share the ground select line GSL. To these ends, the first conductive layers CM1 are connected to one another to form the ground select line GSL.

In the cell strings CS11, CS21, CS12 and CS22, cell transistors at the second through seventh levels operate as first through sixth memory cells MC1˜MC6. The first through sixth memory cells MC1˜MC6 are connected to first through sixth word lines WL1˜WL6, respectively. Memory cells at the same level and disposed in the same row share a word line. Memory cells at the same level and disposed in different rows also share the word line. That is, all the memory cells MC located at the same level in the memory block BLKa share a word line.

The second conductive layers CM2 are connected to form the first common word line WL1. The third conductive layers CM3 are connected to form the second common word line WL2. The fourth conductive layers CM4 are connected to form the third common word line WL3. The fifth conductive layers CM5 are connected to form the fourth word common line WL4. The sixth conductive layers CM6 are connected to form the fifth common word line WL5. The seventh conductive layers CM7 are connected to form the sixth common word line WL6.

In the cell strings CS11, CS21, CS12 and CS22, cell transistors disposed at the eighth level operate as string select transistors SST. The string select transistors SST are connected to first and second string select lines SSL1 and SSL2. Cell strings in the same row share a string select line. Cell strings in the different rows are connected to different string select lines. The first and second string select lines SSL1 and SSL2 are provided by the eighth conductive layers CM8. Thus, rows of the cell strings CS11, CS21, CS12 and CS22 may be defined by the first and second string select lines SSL1 and SSL2, respectively.

The common source line CSL is connected to the cell strings CS11, CS21, CS12 and CS22. For example, the first through third doping regions 311˜313 may be connected to one another to form the common source line CSL (refer to FIGS. 4 through 6).

As described above, the string select lines SSL1 and SSL2, the word lines WL1˜WL6 and the ground select line GSL of the selected memory block are connected to the address decoder 130 through the pass circuits of the block gating unit 120. The address decoder 130 selects the string select lines SSL1 and SSL2, the word lines WL1˜WL6 and the ground select line GSL of the selected memory block.

Memory cells disposed at the same level are connected to one word line, i.e., a common word line. Thus, when a word line at a specific level is selected, all the cell strings CS11, CS12, CS21 and CS22 connected to the selected word line are selected.

Different rows of cell strings are connected to different select lines, respectively. In this example, therefore, rows of the cell strings (CS11 and CS12, or CS21 and CS22) can be selected or unselected by selecting or unselecting the first and second string select lines SSL1 and SSL2. Thus, by selecting one of the first and second string select lines SSL1 and SSL2 and unselecting the other of the string select lines SSL1 and SSL2, the unselected row of cell strings CS11 and CS12, or CS21 are electrically disconnected from the bit lines BL1 and BL2, whereas the selected row of cell strings (e.g., CS21 and CS22, or CS11 and CS12) are electrically connected to the bit lines BL1 and BL2. A respective cell string in the selected row can be selected by selecting one the bit lines BL1 and BL2. That is, the columns of cells strings can be selected and unselected by selecting and unselecting the bit lines BL1 and BL2.

The string select lines SSL1 and SSL2, the word lines WL1˜WL6 and the ground select line GSL of the unselected memory blocks are electrically isolated from the address decoder 121 through a pass circuit of the peripheral circuit region 120 corresponding to the unselected memory blocks. Ground circuits of the peripheral circuit region 120 corresponding to the unselected memory blocks supply a low voltage, for example, a ground voltage VSS to the string select transistors SST and the ground select transistors GST of the unselected memory blocks. Thus, the string select transistors SST and the ground select transistors GST of the unselected memory blocks are turned off and thereby are electrically isolated from the bit lines BL1 and BL2 and the common source line CSL.

In the example of the memory block BLKa shown in and described above with reference to FIGS. 5 through 9, the memory block BLKa has eight levels (of cell transistors) and includes two rows and two columns of cell strings.

However, i.e., in another embodiment, the number of levels of the memory block BLKa corresponds to the number of the cell strings. For example, the memory blocks BLKa may have eight levels, and eight rows and columns of cell strings. In this example, eight string select lines and one ground select line may be connected to the memory blocks BLKa. In another example, the memory block BLKa has sixteen levels, and sixteen rows and columns of cell strings. In this example, sixteen string select lines and one ground select line may be connected to the memory blocks BLKa. Thus, in these examples, the memory block BLKa is characterized by cell strings each having n levels of cell transistors, n rows of the cells stings, n columns of the cell strings, n string select lines and one ground select line.

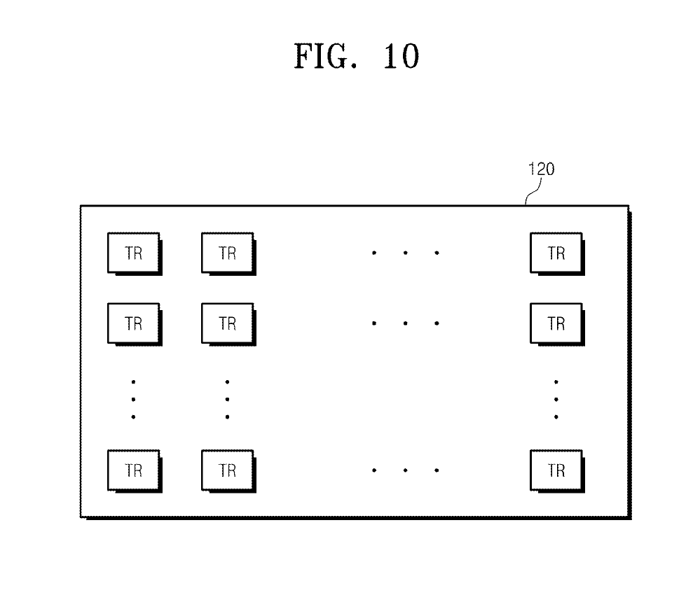

Referring to FIG. 10, the peripheral circuit region 120 may include a plurality of transistors TR. Each transistor TR may include a gate electrode and source and drain regions symmetrical with respect to the gate electrode. Source and drain regions of each transistor TR can be connected to metal layer ML through a plurality of peripheral plugs PPLG.

In FIG. 10, the transistors TR are illustrated as arrayed along the first and third directions. However, the arrangement of the transistors TR is not limited to such a two-dimensional array. The transistors TR may be disposed at any place on the substrate of the peripheral circuit region 120.

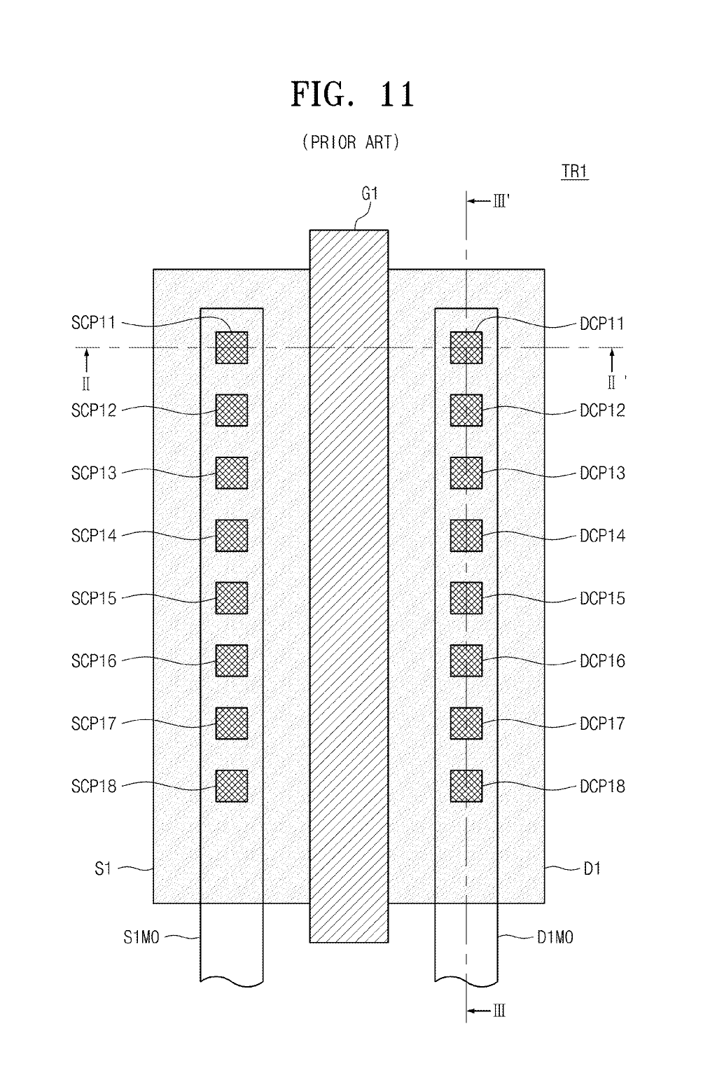

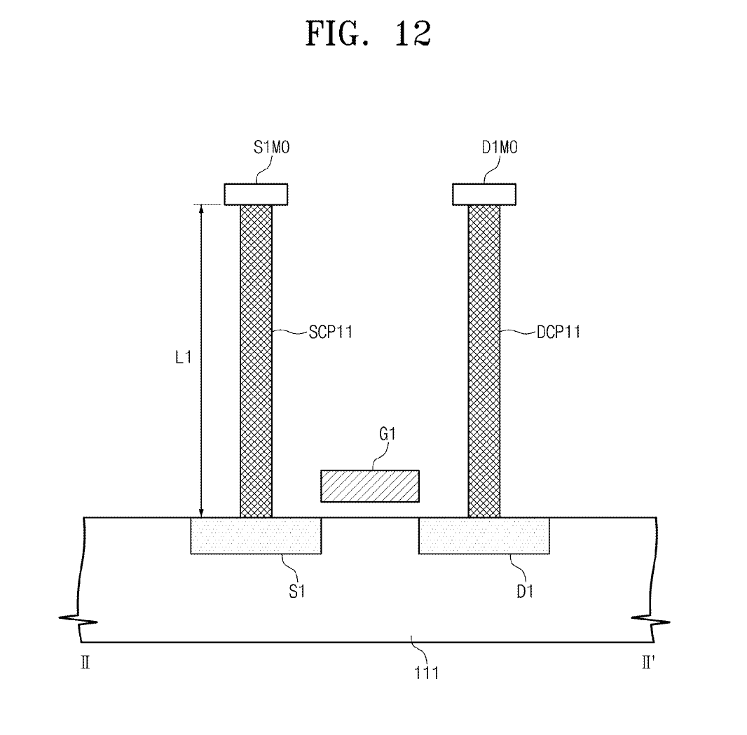

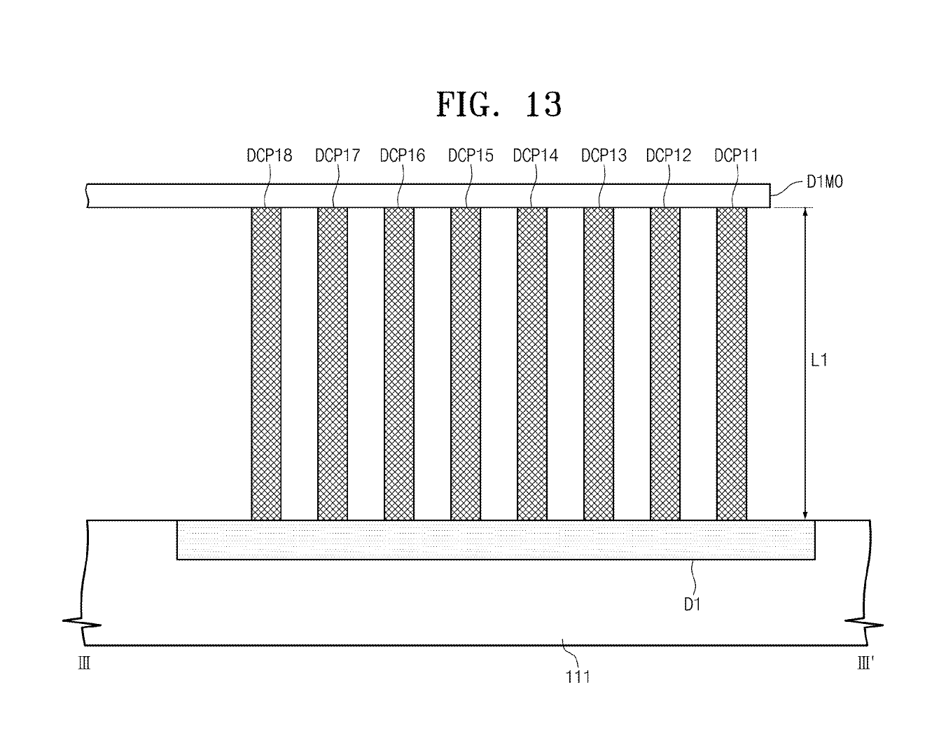

FIGS. 11-13 illustrate an example of a transistor TR1.

Referring to FIGS. 11 through 13, the transistor TR1 may include a gate electrode G1 and a source region S1 and a drain region D1 disposed on both sides of the gate electrode G1. The source region S1 and the drain region D1 may be formed in a substrate. The gate electrode G1 may extend lengthwise in a direction crossing the source region S1 and the drain region D1.

Source contact plugs SCP11˜SCP18 may be disposed between the source region S1 and a source metal line S1M0. The source contact plugs SCP11˜SCP18 correspond to the first peripheral plugs PPLG1 of FIG. 4. The source region S1 can be connected to the source metal line S1M0 through the source contact plugs SCP11˜SCP18. The source metal line S1M0 may constitute the lowest wiring layer of a metal layer corresponding to the metal layer ML of FIG. 3. Drain contact plugs DCP11˜DCP18 may be disposed between the drain region D1 and a drain metal line D1M0. The drain contact plugs DCP11˜DCP18 may correspond to the second peripheral plugs PPLG2 of FIG. 4. The drain region D1 can be connected to the drain metal line D1M0 through the drain contact plugs DCP11˜DCP18. The drain metal line D1M0 may also constitute the lowest wiring layer of a metal layer corresponding to the metal layer ML of FIG. 3.

The source contact plugs SCP11˜SCP18 are spaced from each other at regular intervals and the drain contact plugs DCP11˜DCP18 are spaced from each other at regular intervals.

The source contact plugs SCP11˜SCP18 are symmetrically disposed to the drain contact plugs DCP11˜DCP18 with respect to the gate electrode G1. Specifically, the drain contact plug DCP11 is disposed symmetrically to the source contact plug SCP11 with respect to the gate electrode G1. The drain contact plug DCP12 is disposed symmetrically to the source contact plug SCP12 with respect to the gate electrode G1. The drain contact plug DCP13 is disposed symmetrically to the source contact plug SCP13 with respect to the gate electrode G1. The drain contact plug DCP14 is disposed symmetrically to the source contact plug SCP14 with respect to the gate electrode G1. The drain contact plug DCP15 is disposed symmetrically to the source contact plug SCP15 with respect to the gate electrode G1. The drain contact plug DCP16 is disposed symmetrically to the source contact plug SCP16 with respect to the gate electrode G1. The drain contact plug DCP17 is disposed symmetrically to the source contact plug SCP17 with respect to the gate electrode G1. The drain contact plug DCP18 is disposed symmetrically to the source contact plug SCP18 with respect to the gate electrode G1.

Each of the source contact plugs SCP11˜SCP18 and the drain contact plugs DCP11˜DCP18 may have a first length L1. When applied to a device having the structure shown in FIG. 3, the length L1 of the source and drain contact plugs are more than twice the length L2 of the cell plugs CPLG connected to the memory cell array 110.

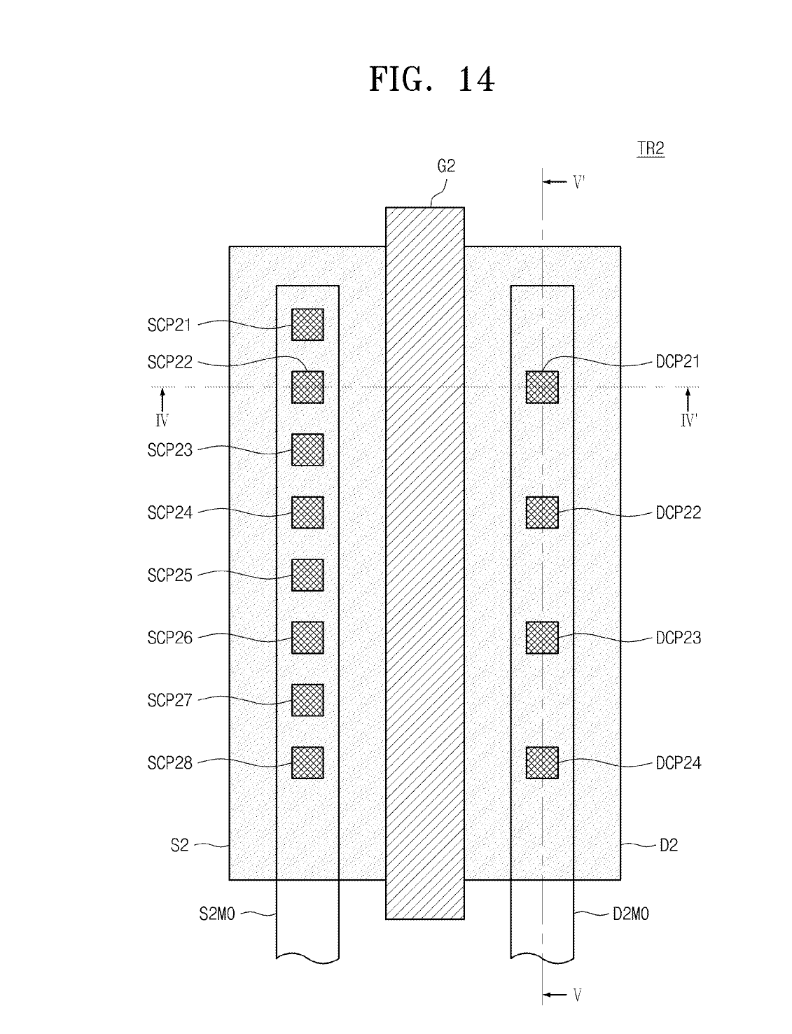

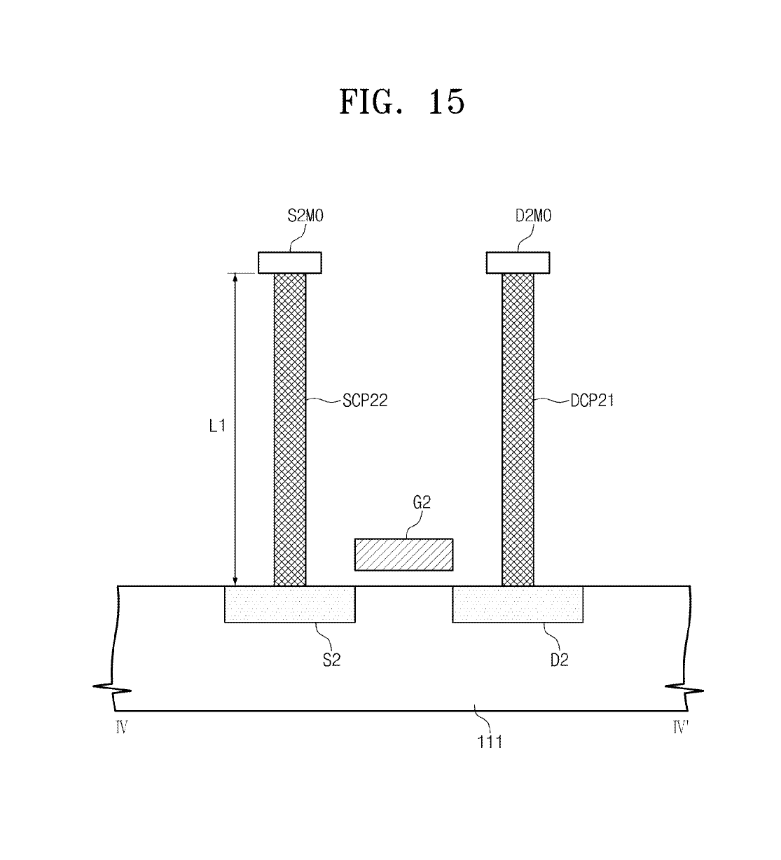

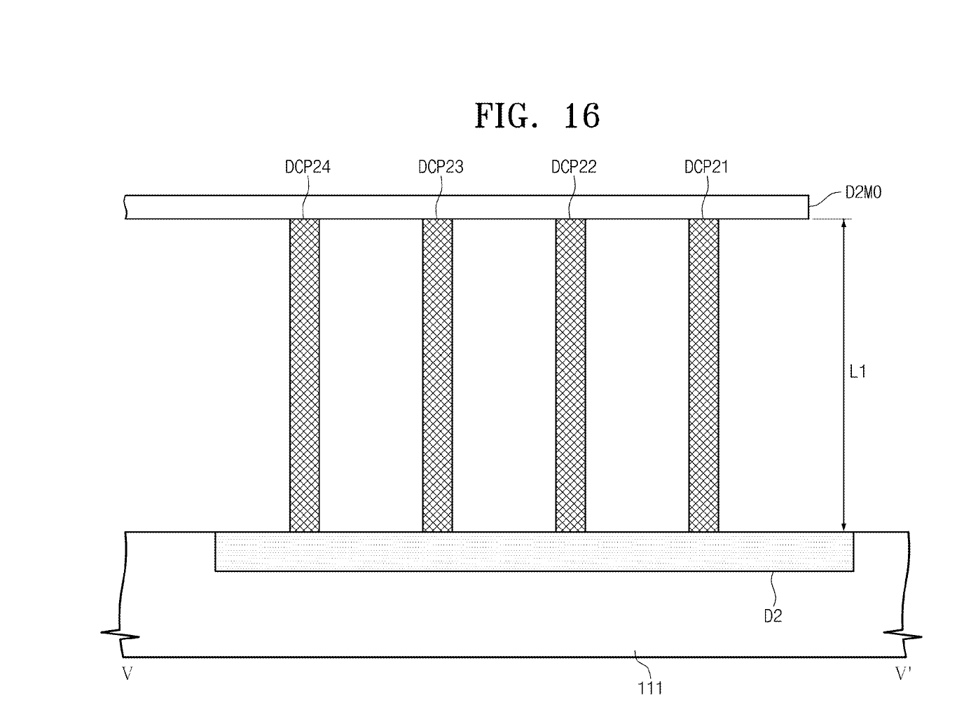

FIGS. 14-16 illustrate one embodiment of a non-volatile memory device according to the inventive concept, as exemplified by a transistor TR2 that may be constitute any of the transistors TR of the peripheral circuit region of FIG. 10.

Referring to FIGS. 14 through 16, the transistor TR2 may include a gate electrode G2 and a source region S2 and a drain region D2 disposed on both sides of the gate electrode G2. The source region S2 and the drain region D2 may be formed in a substrate. The gate electrode G2 may extend in a direction crossing the source region S2 and the drain region D2.

Source contact plugs SCP21˜SCP28 may be disposed between the source region S2 and a source metal line S2M0. The source contact plugs SCP21˜SCP28 correspond to the first peripheral plugs PPLG1 of FIG. 4, in this example. The source region S2 can be connected to the source metal line S2M0 through the source contact plugs SCP21˜SCP28. The source metal line S2M0 may constitute the lowest wiring layer of the metal layer ML of FIG. 3. Drain contact plugs DCP21˜DCP24 may be disposed between the drain region D2 and a drain metal line D2M0. The drain contact plugs DCP21˜DCP24 correspond to the second peripheral plugs PPLG2 of FIG. 4. The drain region D2 can be connected to the drain metal line D2M0 through the drain contact plugs DCP21˜DCP24. The drain metal line D2M0 may also constitute the lowest wiring layer of the metal layer ML of FIG. 3.

The number of the source contact plugs SCP21˜SCP28 is different from the number of the drain contact plugs DCP21˜DCP24 in this example. FIG. 14 illustrates that the transistor TR2 has twice as many source contact plugs SCP21˜SCP28 as drain contact plugs DCP21˜DCP24. However, the inventive concept is not limited thereto. The number of the drain contact plugs may be at least one less than the number of the source contact plugs. Each of the drain contact plugs DCP21˜DCP24 may be disposed symmetrically to a respective one of the source contact plugs SCP21˜SCP28 with respect to the gate electrode G2. For example, the drain contact plug DCP21 may be disposed symmetrically to the source contact plug SCP22 with respect to the gate electrode G2. The drain contact plug DCP22 may be disposed symmetrically to the source contact plug SCP24 with respect to the gate electrode G2. The drain contact plug DCP23 may be disposed symmetrically to the source contact plug SCP26 with respect to the gate electrode G2. The drain contact plug DCP24 may be disposed symmetrically to the source contact plug SCP28 with respect to the gate electrode G2.

In the example shown in FIG. 14, the drain region D2 of the transistor TR2 is connected to the drain metal line D2M0 through a number of drain contact plugs DCP21˜DCP24 smaller than the number of source contact plugs SCP21˜SCP28. The spacing between adjacent ones of the drain contact plugs DCP21˜DCP24, i.e., the pitch of the drain contact plugs, may be greater than the spacing between adjacent ones of the source contact plugs SCP21˜SCP28. Thus, the capacitance of the transistor TR2 may be less than that of the transistor TR1 of FIG. 11. A propagation delay of the transistor TR2 may be shorter than that of the transistor TR1 of FIG. 11.

The length L1 of the source contact plugs SCP21˜SCP28 and the drain contact plugs DCP21˜DCP24, as illustrated in FIG. 3, may be more than twice the length L2 of the cell plugs CPLG connected to the memory cell array 110.

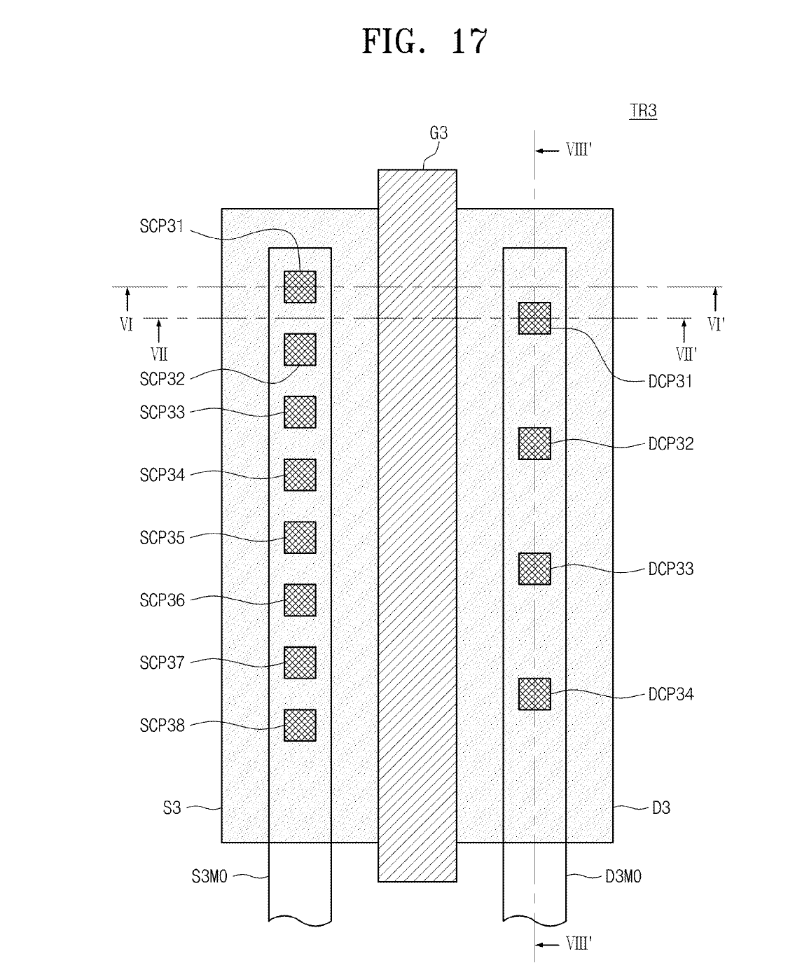

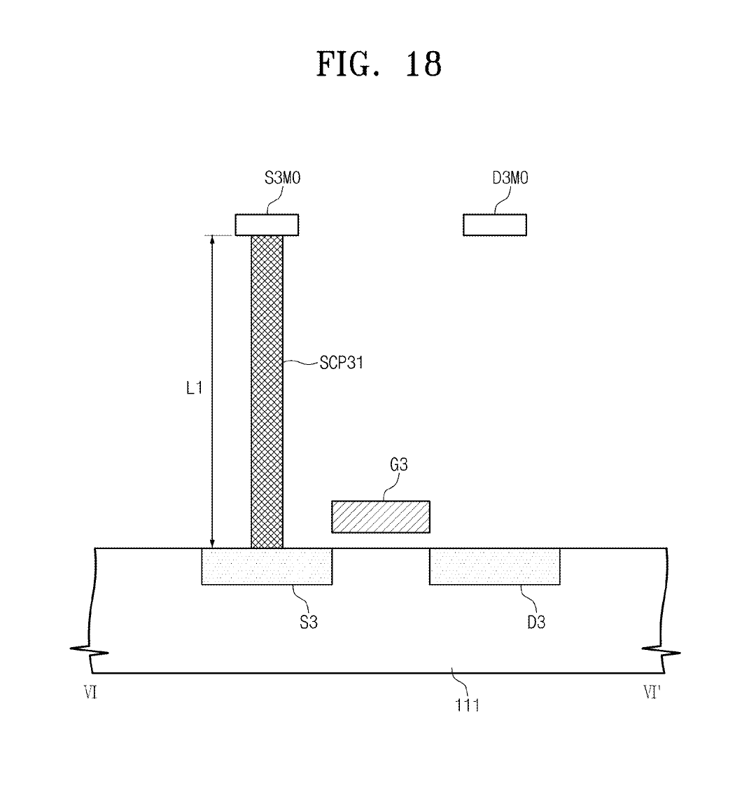

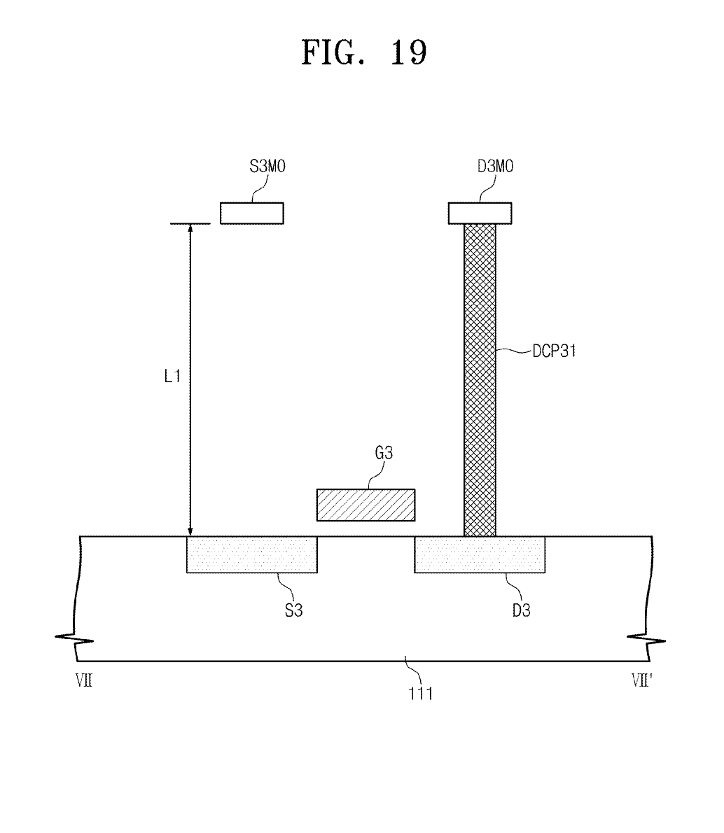

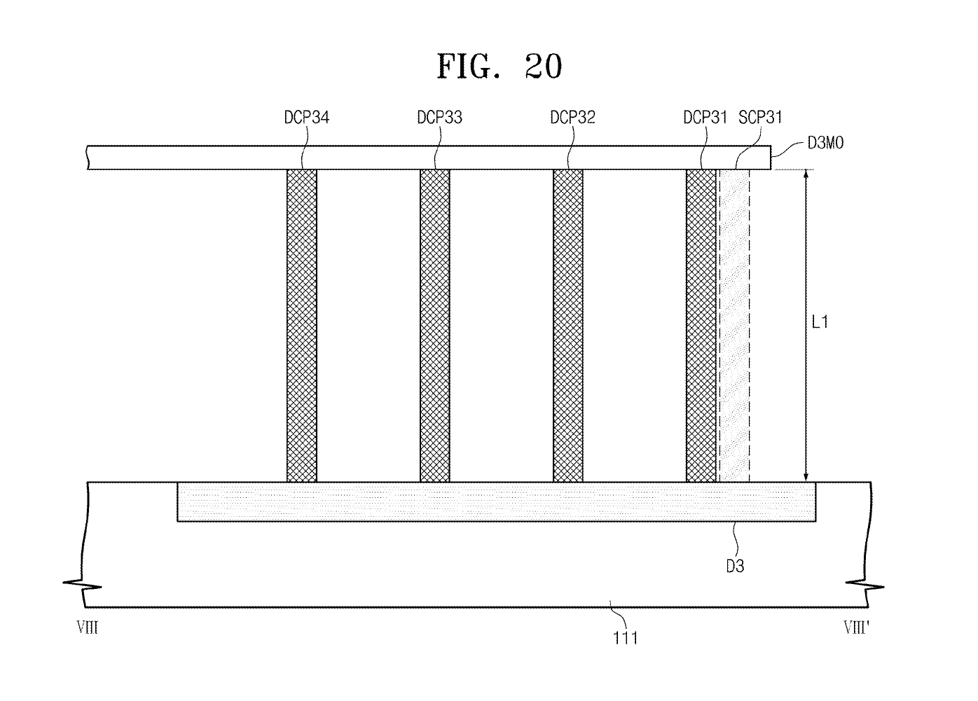

FIGS. 17-20 illustrate another embodiment of a non-volatile memory device according to the inventive concept, as exemplified by a transistor TR3 that may be constitute any of the transistors TR of the peripheral circuit region of FIG. 10.

Referring to FIGS. 17 through 20, the transistor TR3 may include a gate electrode G3 and a source region S3 and a drain region D3 disposed on both sides of the gate electrode G3. The source region S3 and the drain region D3 may be formed on a substrate. The gate electrode G3 may extend lengthwise in a direction crossing the source region S3 and the drain region D3.

Source contact plugs SCP31˜SCP38 may be disposed between the source region S3 and a source metal line S3M0. The source contact plugs SCP31˜SCP38 may constitute the first peripheral plugs PPLG1 of FIG. 4. The source region S3 can be connected to the source metal line S3M0 through the source contact plugs SCP31˜SCP38. The source metal line S3M0 may be the lowest wiring layer of the metal layer ML of FIG. 3. Drain contact plugs DCP31˜DCP34 may be disposed between the drain region D3 and a drain metal line D3M0. The drain contact plugs DCP31˜DCP34 may constitute the second peripheral plugs PPLG2 of FIG. 4. The drain region D3 can be connected to the drain metal line D3M0 through the drain contact plugs DCP31˜DCP34. The drain metal line D3M0 may constitute the lowest wiring layer of the metal layer ML of FIG. 3.

The number of the source contact plugs SCP31˜SCP38 are different from the number of the drain contact plugs DCP31˜DCP34. FIG. 17 illustrates an example in which the number of source contact plugs SCP31˜SCP38 is twice the number of drain contact plugs DCP31˜DCP34. However, the inventive concept is not limited thereto. The number of the drain contact plugs may be at least one less than the number of the source contact plugs.

Each of the central longitudinal axes of the drain contact plugs DCP31˜DCP34 may be disposed at a position which is symmetrical to a point between any two adjacent ones of the source contact plugs SCP31˜SCP38, with respect to the gate electrode G3. Likewise, each of the drain contact plugs DCP31˜DCP34 may be disposed at a position which is symmetrical to a region between any two adjacent ones of a respective pair of the source contact plugs SCP31˜SCP38, with respect to the gate electrode G3. For example, the drain contact plug DCP31 may be disposed at a position which is symmetrical to any point or the region between the source contact plugs SCP31 and SCP32 with respect to the gate electrode G3. The drain contact plug DCP32 may be disposed at a position which is symmetrical to any point or the region between the source contact plugs SCP33 and SCP34 with respect to the gate electrode G3. The drain contact plug DCP33 may be disposed at a position which is symmetrical to any point or the region between the source contact plugs SCP35 and SCP36 with respect to the gate electrode G3. The drain contact plug DCP34 may be disposed at a position which is symmetrical to any point or the region between the source contact plugs SCP37 and SCP38 with respect to the gate electrode G3.

In the embodiment of FIG. 17, the drain region D3 of the transistor TR3 is connected to the drain metal line D3M0 through a number of drain contact plugs DCP31˜DCP34 that is less than the number of source contact plugs SCP31˜SCP38. The spacing between adjacent ones of the drain contact plugs DCP31˜DCP34, i.e., the pitch of the drain contact plugs, may be greater than the spacing between adjacent ones of the source contact plugs SCP31˜SCP38. The drain contact plugs DCP31˜DCP34 are disposed asymmetrically to the source contact plugs SCP31˜SCP38 with respect to the gate electrode G3. The distance between any one of the source contact plugs SCP31˜SCP38 and any one of the drain contact plugs DCP31˜DCP34 may be greater than in the cases of the transistors TR2 and TR3 of FIGS. 11 and 14. Thus, the transistor TR3 may have a smaller capacitance compared to the transistors TR2 and TR3 of FIGS. 11 and 14. A propagation delay of the transistor TR3 may be shorter than in the case of the transistors TR2 and TR3 of FIGS. 11 and 14.

Also, the length L1 of the source contact plugs SCP31˜SCP38 and the drain contact plugs DCP31˜DCP34, as illustrated in FIG. 3, may be more than twice the length L2 of the cell plugs CPLG connected to the memory cell array 110.

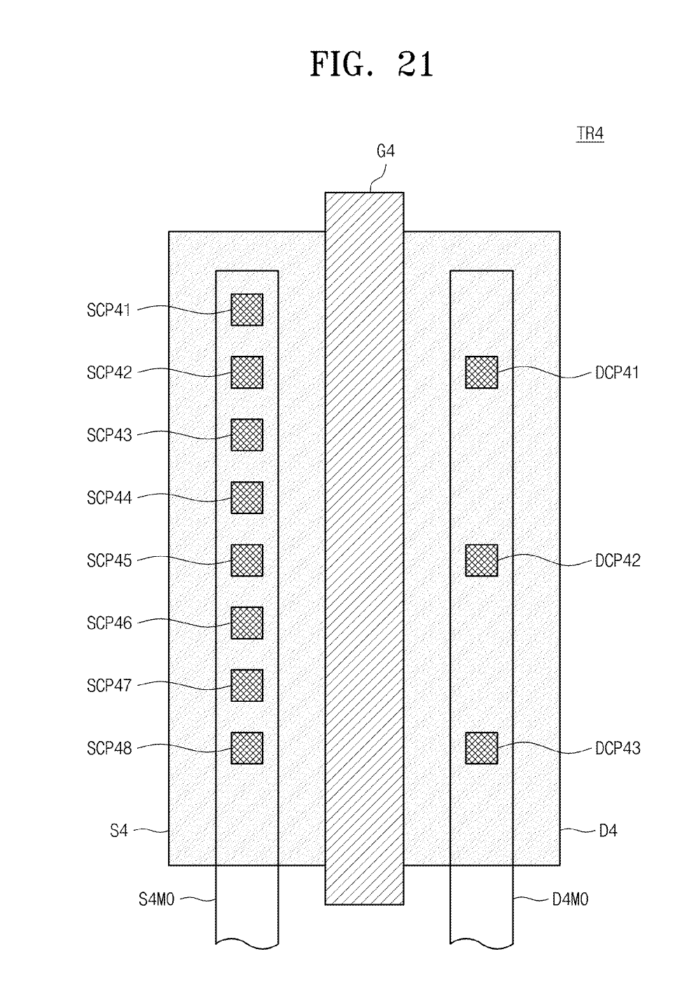

FIG. 21 illustrates still another embodiment of a non-volatile memory device according to the inventive concept, as exemplified by a transistor TR4 that may be constitute any of the transistors TR of the peripheral circuit region of FIG. 10. Referring to FIG. 21, the transistor TR4 may include a gate electrode G4 and a source region S4 and a drain region D4 disposed on both sides of the gate electrode G4.

The drain region D4 of the transistor TR4 is connected to the drain metal line D4M0 through drain contact plugs DCP41˜DCP43. The transistor TR4 is similar to the transistor T2 illustrated in FIGS. 14 through 16 except that FIG. 21 illustrates a case in which a different number of drain contact plugs, i.e., three drain contact plugs DCP41˜DCP43, are provided. As mentioned before, though, any number of drain contact plugs may be provided as long there are fewer drain contact plugs than source contact plugs, i.e., the number of drain contact plugs is one or more than one less than the number of source contact plugs.

Each of the drain contact plugs DCP41˜DCP43 may be disposed symmetrically to one of the source contact plugs SCP41˜SCP48 with respect to the gate electrode G4. For example, the drain contact plug DCP41 may be disposed symmetrically to the source contact plug SCP42 with respect to the gate electrode G4. The drain contact plug DCP42 may be disposed symmetrically to the source contact plug SCP45 with respect to the gate electrode G4. The drain contact plug DCP43 may be disposed symmetrically to the source contact plug SCP48 with respect to the gate electrode G4.

In FIG. 21, the drain region D4 of the transistor TR4 is connected to the drain metal line D4M0 through a number of drain contact plugs DCP41 DCP43 which is smaller than the number of source contact plugs SCP41˜SCP48. The spacing between adjacent ones of the drain contact plugs DCP41˜DCP43, i.e., the pitch of the drain contact plugs, may be greater than that between adjacent ones of the source contact plugs SCP41˜SCP48. Thus, the transistor TR4 may have a smaller capacitance compared to the case of the transistor TR1 of FIG. 11. A propagation delay of the transistor TR4 may be shorter compared to the case of the transistor TR1 of FIG. 11.

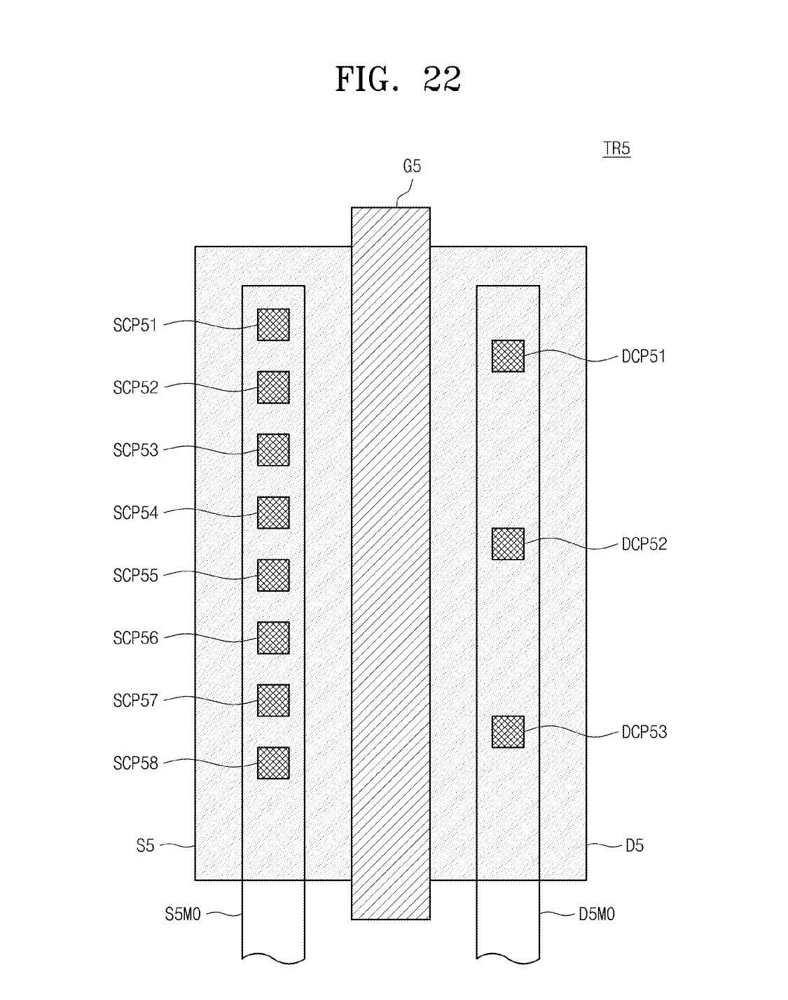

FIG. 22 illustrates still another embodiment of a non-volatile memory device according to the inventive concept, as exemplified by a transistor TR5 that may be constitute any of the transistors TR of the peripheral circuit region of FIG. 10. Referring to FIG. 22, the transistor TR5 may include a gate electrode G5 and a source region S5 and a drain region D5 disposed on both sides of the gate electrode G5.

The drain region D5 of the transistor TR5 is connected to the drain metal line D5M0 through drain contact plugs DCP51˜DCP53. The transistor TR5 is similar to the transistor T32 illustrated in FIGS. 17 through 20 except that FIG. 22 illustrates a case in which a different number of drain contact plugs, i.e., three drain contact plugs DCP51˜DCP53, are provided. As mentioned before, though, any number of drain contact plugs may be provided as long there are fewer drain contact plugs than source contact plugs, i.e., the number of drain contact plugs is one or more than one less than the number of source contact plugs.

Each of the drain contact plugs DCP51˜DCP53 is disposed at a position which is symmetrical to any point or the entire region between adjacent ones of the source contact plugs SCP51˜SCP58, with respect to the gate electrode G5. For example, the drain contact plug DCP51 may be disposed at a position which is symmetrical to any point or the region between the source contact plugs SCP51 and SCP52 with respect to the gate electrode G5. The drain contact plug DCP52 may be disposed at a position which is symmetrical to any point or the region between the source contact plugs SCP54 and SCP55 with respect to the gate electrode G5. The drain contact plug DCP53 may be disposed at a position which is symmetrical to any point or the region between the source contact plugs SCP57 and SCP58 with respect to the gate electrode G5.

In FIG. 22, the drain region D5 of the transistor TR5 is connected to the drain metal line D5M0 through a number of drain contact plugs DCP51˜DCP53 which is smaller than the number of source contact plugs SCP51˜SCP58. The spacing between adjacent ones of the drain contact plugs DCP51˜DCP53, i.e., the pitch of the drain contact plugs, may be greater than the spacing between adjacent ones of the source contact plugs SCP51˜SCP58. The drain contact plugs DCP51˜DCP53 are disposed asymmetrically to the source contact plugs SCP51˜SCP58 with respect to the gate electrode G5. The distance between any one of the source contact plugs SCP51˜SCP58 and the closest one of the drain contact plugs DCP51˜DCP53 may be greater than in the case of any of the transistors TR1, TR2 and TR4 of FIGS. 11, 14 and 21. Thus, the transistor TR5 may have a smaller capacitance compared to the transistors TR1, TR2 and TR4 of FIGS. 11, 14 and 21. A propagation delay of the transistor TR5 may be shorter compared to the transistors TR1, TR2 and TR4 of FIGS. 11, 14 and 21.

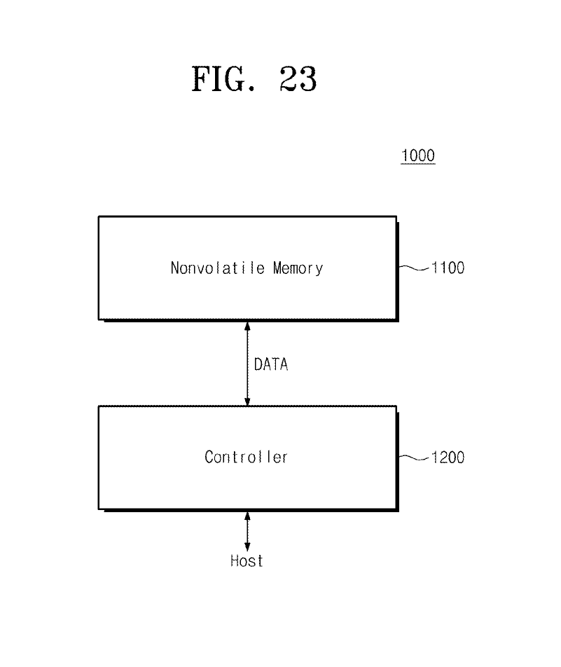

FIG. 23 is a block diagram illustrating a memory system in accordance with some embodiments of the inventive concept. Referring to FIG. 23, the memory system 1000 includes a nonvolatile memory device 1100 and a controller 1200.

The nonvolatile memory device 1100 may be any nonvolatile memory device 100 described with reference to FIGS. 1 through 20. Thus, the transistors in the peripheral circuit region may have a relatively small capacitance. Accordingly, the propagation in the peripheral circuit region may be relatively short.

The nonvolatile memory device 1100 may include at least one of various nonvolatile memory devices such as an EEPROM (electrically erasable and programmable ROM), a flash memory, a PRAM (phase change RAM), a RRAM (resistive RAM), or a FRAM (ferroelectric RAM).

The controller 1200 is connected to the nonvolatile memory device 1100. The controller 1200 is configured to access the nonvolatile memory device 1100. For example, the controller 1200 is configured to control read, write, erase and background operations of the nonvolatile memory device 1100. The controller 1200 is configured to provide an interface between the nonvolatile memory device 1100 and a host. The controller 1200 is configured to drive firmware for controlling the nonvolatile memory device 1100.

The controller 1200 may include constituent elements such as a RAM, a processing unit, a host interface, a memory interface, and an error correction unit.

The controller 1200 can communicate with an external device (for example, a host) according to a specific communication standards. The controller 1200 is configured to communicate with an external device through at least one of various communication standards such as a USB (universal serial bus), a MMC (multimedia card), a PCI (peripheral component interconnection), a PCI-E (PCI-express), an ATA (advanced technology attachment), a serial-ATA, a parallel-ATA, a SCSI (small computer small interface), an ESDI (enhanced small disk interface), an IDE (integrated drive electronics) or a firewire.

The controller 1200 and the nonvolatile memory device 1100 can be integrated in one semiconductor device. For example, the controller 1200 and the nonvolatile memory device 1100 can be integrated to constitute a solid state drive SSD. The controller 1200 and the nonvolatile memory device 1100 can be integrated to constitute to a memory card such as a PC card (personal computer memory card international association), a compact flash card CF, a smart media card (SM, SMC), a memory stick, a multimedia card (MMC, RS-MMC, MMCmicro), a SD card (SD, miniSD, microSD, SDHC), a universal flash memory device (UFS), or the like.

In the case in which the controller 1200 and the nonvolatile memory device 1100 are integrated to constitute a solid state drive SSD, the solid state drive SSD includes a storage device configured to store data in a semiconductor memory. In that case, an operation speed of a host connected to the memory system 1000 is greatly improved.

The memory system 1000 can constitute a computer, an ultra mobile PC (UMPC), a workstation, a net-book, a personal digital assistants (PDA), a portable computer, a web tablet, a tablet computer, a wireless phone, a mobile phone, a smart phone, an e-book, a portable multimedia player (PMP), a portable game machine, a navigation device, a black box, a digital camera, a digital multimedia broadcasting (DMB) player, a three-dimensional television, a smart television, a digital audio recorder, a digital audio player, a digital picture recorder, a digital picture player, a digital video recorder, a digital video player, a storage constituting a data center, a device that can transmit and receive information in a wireless environment, one of various electronic devices constituting a home network, one of various electronic devices constituting a computer network, one of various electronic devices constituting a telematics network, or one of various constituent elements constituting an RFID device or a computing system.

The nonvolatile memory device 1100 or the memory system 1000 can constitute various types of packages such as a PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP) or wafer-level processed stack package (WSP).

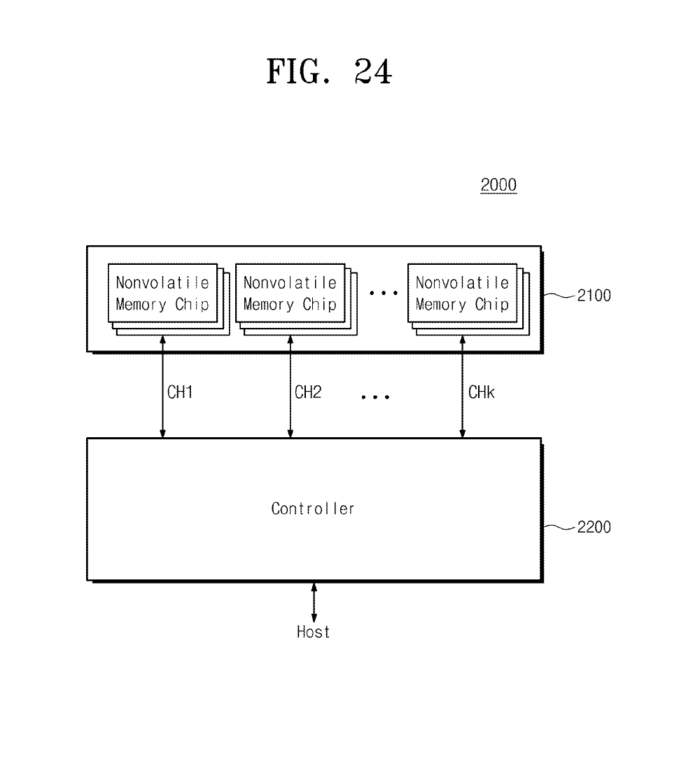

FIG. 24 is a block diagram illustrating a memory system in accordance with some other embodiments of the inventive concept. Referring to FIG. 24, a memory system 2000 includes a nonvolatile memory device 2100 and a controller 2200. The nonvolatile memory device 2100 includes a plurality of nonvolatile memory chips. The nonvolatile memory chips are divided into a plurality of groups. Each group of the nonvolatile memory chips is configured to communicate with the controller 2200 through one common channel. This figure illustrates an example in which the nonvolatile memory chips communicate with the controller 2200 through first through kth channels CH1˜CHk.

Each of the nonvolatile memory chips may be any nonvolatile memory device 100 described with reference to FIGS. 1 through 20.

FIG. 24 illustrates an example in which nonvolatile memory chips are connected to one channel. Alternatively, each nonvolatile memory chip may have its own dedicated channel.

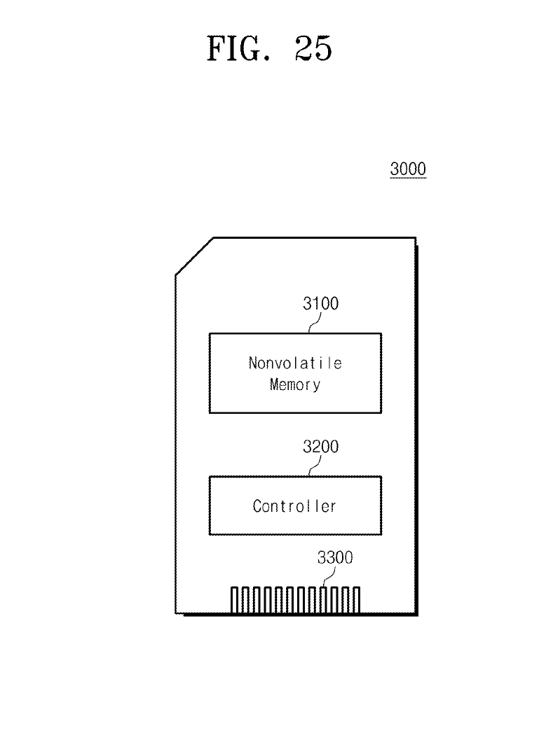

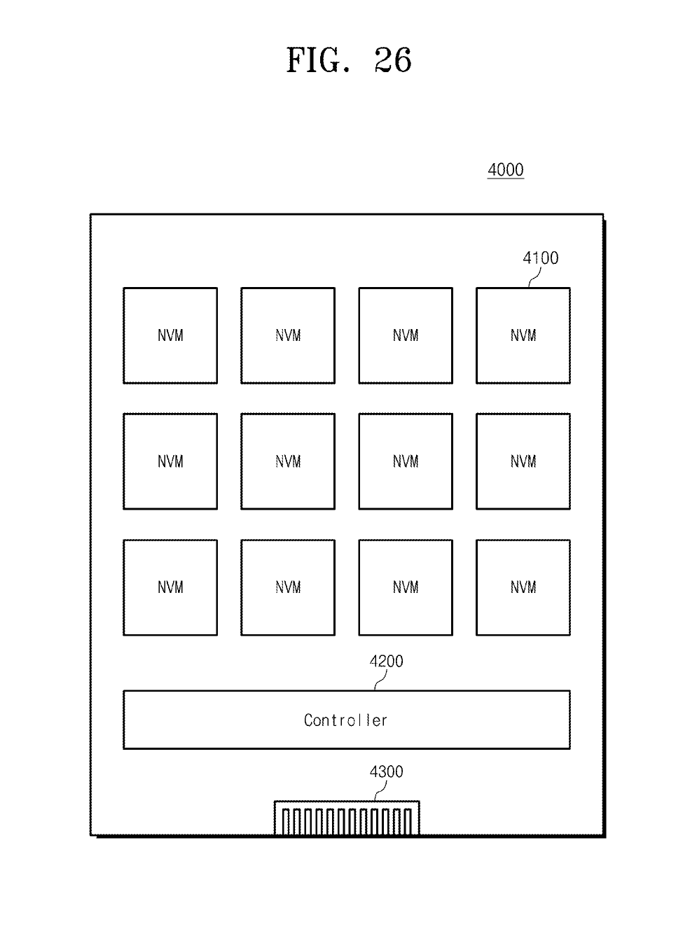

FIG. 25 illustrates a memory card in accordance with some embodiments of the inventive concept. Referring to FIG. 25, a memory card 3000 includes a nonvolatile memory device 3100, a controller 3200 and a connector 3300.

The nonvolatile memory device 3100 may be any nonvolatile memory device 100 described with reference to FIGS. 1 through 20.

The connector 3300 can electrically connect the memory card 3000 to an external device (for example, a host).

The memory card 3000 may be a PC card (personal computer memory card international association), a compact flash card CF, a smart media card (SM, SMC), a memory stick, a multimedia card (MMC, RS-MMC, MMCmicro), a SD card (SD, miniSD, microSD, SDHC), a universal flash memory device (UFS), or the like.

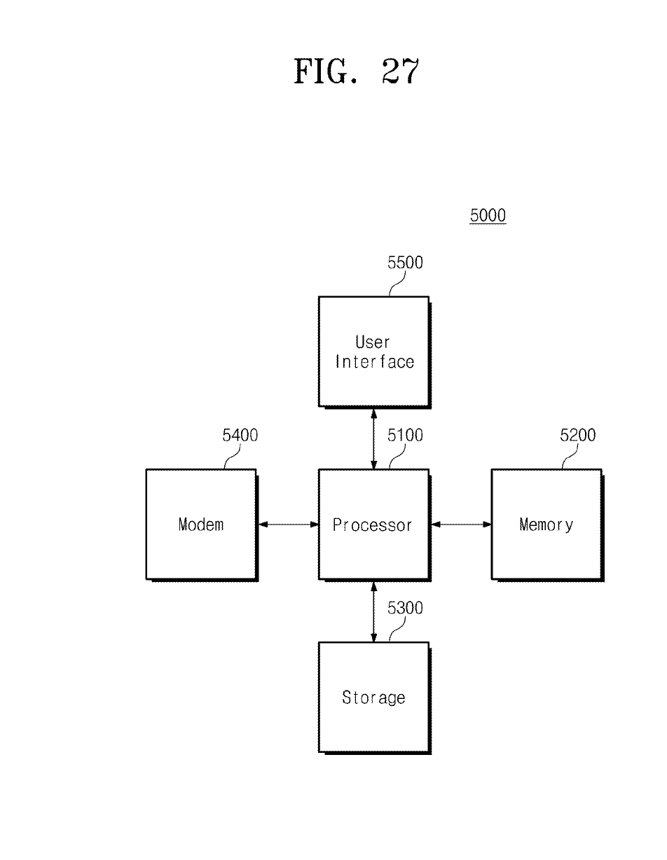

FIG. 26 illustrates a solid state drive in accordance with some embodiments of the inventive concept. Referring to FIG. 26, a solid state drive 4000 includes a plurality of nonvolatile memory devices 4100, a controller 4200, and a connector 4300.

The nonvolatile memory device 4100 may be any nonvolatile memory device 100 described with reference to FIGS. 1 through 20.

The connector 4300 can electrically connect the memory card 4000 to an external device (for example, a host).

FIG. 27 illustrates a computing device in accordance with some embodiments of the inventive concept. Referring to FIG. 27, a computing device 5000 includes a processor 5100, a memory 5200, storage 5300, a modem 5400, and a user interface 5500.

The processor 5100 can control an overall operation of the computing device 5000 and perform a logical operation. For example, the processor 5100 can be constituted by a system-on-chip SoC. The processor 5100 may be a general purpose processor or an application processor.

The memory 5200 can communicate with the processor 5100. The memory 5200 may be an operation memory (or main memory) of the processor 5100 or the computing device 5000. The memory 5200 may include a volatile memory such as a SRAM (static RAM), a DRAM (dynamic RAM), or a SDRAM (synchronous DRAM) and a nonvolatile memory device such as a flash memory, a PRAM (phase-change RAM), a MRAM (magnetic RAM), or a RRAM (resistive RAM), or a FRAM (ferroelectric RAM).

The storage 5300 can store data that needs to be preserved long term. The storage 5300 may include a hard disk drive HDD, or a nonvolatile memory device such as a flash memory, a PRAM (phase-change RAM), a MRAM (magnetic RAM), a RRAM (resistive RAM), or a FRAM (ferroelectric RAM).

The storage 5300 may be any nonvolatile memory device 100 described with reference to FIGS. 1 through 20.

The memory 5200 and the storage 5300 may be constituted by the same kind of nonvolatile memory device. The memory 5200 and the storage 5300 may be constituted by one semiconductor integrated circuit.

The modem 5400 can communicate with an external device under the control of the processor 5100. The modem 5400 can perform a wired or wireless communication with an external device. The modem 5400 can perform a communication on the basis of at least one of various wireless communication methods such as a long term evolution (LTE), a WiMax, a global system for mobile communication (GSM), a code division multiple access (CDMA), a Bluetooth, a near field communication (NFC), a WiFi, a radio frequency Identification (RFID), or at least one of various wired communication methods such as a universal serial bus (USB), a serial at attachment (SATA), a small computer small interface (SCSI), a Firewire, or a peripheral component interconnection (PCI).

The user interface 5500 can communicate with a user under the control of the processor 5100. For example, the user interface 5500 may include user input interfaces such as a keyboard, a keypad, a button, a touch panel, a touch screen, a touch pad, a touch ball, a camera, a mike, a gyroscope sensor, a vibration sensor, or the like. The user interface 5500 may include user output interfaces such as a liquid crystal display (LCD), an organic light emitting diode (OLED) display, an active matrix OLED (AMOLED) display, a LED, a speaker, or a motor.

As described above, embodiments of the inventive concept include a nonvolatile memory device which minimizes propagation delay through the provision of an asymmetrical arrangement between contact plugs of a source region and the contact plugs of a drain region of a transistor of the device.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiments and examples described above but by the following claims.

What is claimed is:

1. A nonvolatile memory device comprising:
a memory cell array including a plurality of cell strings, each of the cell strings including a plurality of memory cells stacked in a direction perpendicular to a substrate; and
a peripheral circuit region including transistors, source contact plugs and drain contact plugs,
wherein the transistors are electrically connected to the memory cell array through the source contact plugs, the drain contact plugs, and conductive lines connected to the source and drain contact plugs,
each of the transistors includes a gate electrode crossing an active region of the substrate in a first direction, and source and drain regions at both sides of the gate electrode, and
in at least one of the transistors, respective ones of the source and drain contact plugs are connected to the source and drain regions, respectively, and the number of source contact plugs connected to the source region is different from the number of drain contact plugs connected to the drain region.

2. The nonvolatile memory device of claim 1, wherein in each said at least one of the transistors, the number of the drain contact plugs connected to the drain region is at least one less than the number of the source contact plugs connected to the source region.

3. The nonvolatile memory device of claim 1, wherein in each said at least one of the transistors, the number of the drain contact plugs connected to the drain region is half of the number of the source contact plugs connected to the source region.

4. The nonvolatile memory device of claim 1, wherein in each said at least one of the transistors, the drain contact plugs connected to the drain region are disposed symmetrically to the source contact plugs connected to the source region with respect to the gate electrode.

5. The nonvolatile memory device of claim 1, wherein in each said at least one of the transistors, the drain contact plugs are disposed symmetrically to a point between adjacent ones of the source contact plugs with respect to the gate electrode.

6. The nonvolatile memory device of claim 1, wherein in each said at least one of the transistors, the drain contact plugs are offset from the source contact plugs in the first direction such that the shortest distance between each of the drain contact plugs and any of the source contact plugs is along a diagonal line that is oblique with respect to the first direction.

7. The nonvolatile memory device of claim 1, wherein the heights of the source and drain contact plugs relative to a top surface of the substrate are the same.

8. The nonvolatile memory device of claim 1, wherein the heights of the source and drain contact plugs are the same as the distance between a top surface of the substrate and a lowest one of the conductive lines.

9. A nonvolatile memory device comprising:
a memory cell array including a plurality of cell strings, each of the cell strings including a plurality of memory cells stacked in a direction perpendicular to a substrate; and
a peripheral circuit region including a plurality of transistors electrically connected to the memory cell array through a plurality of conductive lines, source contact plugs and drain contact plugs,
wherein each of the transistors includes a gate electrode crossing an active region of the substrate a first direction and source and drain regions in the active region of both sides of the gate electrode, and
in at least one of the transistors, respective ones of the source and drain contact plugs are connected to the source and drain regions, respectively, and the spacing between the source contact plugs connected to the source region is different from the spacing between the drain contact plugs connected to the drain region.

10. The nonvolatile memory device of claim 9, wherein in said at least one of the transistors, the spacing between adjacent ones of the drain contact plugs is twice the spacing between adjacent ones of the source contact plugs.

11. The nonvolatile memory device of claim 9, wherein in said at least one of the transistors, the spacing between adjacent ones of the drain contact plugs is greater than the spacing between adjacent ones of the source contact plugs.

12. The nonvolatile memory device of claim 11, wherein in said at least one of the transistors, each of the drain contact plugs is disposed symmetrically to one of the source contact plugs with respect to the gate electrode.

13. The nonvolatile memory device of claim 11, wherein in said at least one of the transistors, each of the drain contact plugs is disposed symmetrically to a point lying between adjacent ones of the source contact plugs, with respect to the gate electrode.

14. The nonvolatile memory device of claim 11, wherein in said at least one of the transistors, the drain contact plugs are offset from the source contact plugs in the first direction such that the shortest distance between each of the drain contact plugs and any of the source contact plugs is along a diagonal line that is oblique with respect to the first direction.

15. The nonvolatile memory device of claim 9, wherein in said at least one of the transistors, the drain contact plugs are arranged in a line along the first direction, and the source contact plugs are arranged in a line along the first direction.

16. A nonvolatile memory device having a cell array region and a peripheral circuit region, the device comprising:
an array of memory cell transistors in the cell array region, the memory cell transistors comprising memory cells stacked in a vertical direction;
a horizontal array of peripheral transistors in the peripheral circuit region, each of the peripheral transistors including a gate electrode and source and drain regions at opposite sides of the gate electrode, respectively;
source and drain contact plugs extending vertically from the source and drain regions of the peripheral transistors; and
an interconnection layer including conductive lines extending in the cell array and peripheral circuit regions, the source contact plugs extending vertically between the source regions and the interconnection layer, the drain contact plugs extending vertically between the drain regions and the interconnection layer, the source and drain contact plugs and the memory cell transistors being electrically connected to the conductive lines such that the interconnection layer electrically connects the peripheral transistors to the memory cell transistors, and
wherein a greater number of the contact plugs extend between the drain region of one of the peripheral transistors and the interconnection layer than between the source region of said one of the peripheral transistors and the interconnection layer.

17. The nonvolatile memory device of claim 16, comprising a three-dimensional array of the memory cell transistors, and a two-dimensional horizontal array of the peripheral transistors electrically connected to the memory cell transistors by the source and drain contact plugs and the interconnection layer.

18. The nonvolatile memory device of claim 16, wherein the gate electrode of said one of the peripheral transistors extends longitudinally in a first direction beyond the bounds of the source region and the drain region of said one of the peripheral transistors,
a plurality of the source contact plugs are aligned with one another in the first direction and each extend vertically between the source region of said one of the peripheral transistors and the interconnection layer, and
a plurality of the drain contact plugs are aligned with one another in the first direction and each extend vertically between the drain region of said one of the peripheral transistors and the interconnection layer.

19. The nonvolatile memory device of claim 18, wherein the spacing between adjacent ones of the aligned source contact plugs is uniform, the spacing between adjacent ones of and the aligned drain contact plugs is uniform, and each of the aligned drain contact plugs is aligned in a direction, perpendicular to the first direction, with a respective one of the aligned source contact plugs.

20. The nonvolatile memory device of claim 18, wherein the spacing between adjacent ones of the aligned source contact plugs is uniform, the spacing between adjacent ones of and the aligned drain contact plugs is uniform, and a central vertical axis of each of the aligned drain contact plugs is aligned in a direction, perpendicular to the first direction, with a point lying between adjacent ones of a respective pair of the aligned source contact plugs.
